(19) United States
(12) Patent Application Publication
(10) Pub. No.: US 2025/0370355 A1
(43) Pub. Date: Dec. 4, 2025

(54) POSITIONING SYSTEM FOR AN OPTICAL ELEMENT OF A METROLOGY APPARATUS

(71) Applicant: ASML NETHERLANDS B.V., Veldhoven (NL)

(72) Inventors: Brandon Michael SUIT, Stamford, CT (US); Bram Antonius Gerardus LOMANS, Eindhoven (NL); Douglas C. CAPPELLI, Norwalk, CT (US); Jason OCHS, Stamford, CT (US)

(73) Assignee: ASML NETHERLANDS B.V., Veldhoven (NL)

(21) Appl. No.: 18/876,184

(22) PCT Filed: Sep. 14, 2023
(86) PCT No.: PCT/EP2023/075306

§ 371 Date: Dec. 17, 2024

Related U.S. Application Data
(60) Provisional application No. 63/409,354, filed on Sep. 23, 2022.

(51) Int. Cl. G03F 7/00

(52) U.S. Cl. CPC G03F 7/70825; G03F 7/70833

(57) ABSTRACT

A positioning system for an optical element such as an objective of a metrology apparatus (e.g., an overlay measurement apparatus used in a semiconductor manufacturing process) is described. The positioning system includes a stage and a positioner. The positioner includes at least one flexible support coupled to the stage, with the at least one flexible support configured to be relatively stiff in an axial direction of the positioner, and relatively flexible in other directions. The positioner includes a base coupled to the at least one flexible support, with the base configured to be actuated to move in the axial direction, and in turn move the stage. The positioner includes a guide configured to couple the base to a frame of the metrology apparatus, with the guide configured to bend when the base is actuated.

### CROSS-REFERENCE TO RELATED APPLICATIONS

This application claims priority of U.S. application 63/409,354 which was filed on 23 Sep. 2022 and which is incorporated herein in its entirety by reference.

### TECHNICAL FIELD

This description relates to a positioning system for an optical element of a metrology apparatus.

### BACKGROUND

A lithographic projection apparatus can be used, for example, in the manufacture of integrated circuits (ICs). A patterning device (e.g., a mask) may include or provide a pattern corresponding to an individual layer of the IC (“design layout”), and this pattern can be transferred onto a target portion (e.g. comprising one or more dies) on a substrate (e.g., silicon wafer) that has been coated with a layer of radiation-sensitive material (“resist”), by methods such as irradiating the target portion through the pattern on the patterning device. In general, a single substrate includes a plurality of adjacent target portions to which the pattern is transferred successively by the lithographic projection apparatus, one target portion at a time. In one type of lithographic projection apparatus, the pattern on the entire patterning device is transferred onto one target portion in one operation. Such an apparatus is commonly referred to as a stepper. In an alternative apparatus, commonly referred to as a step-and-scan apparatus, a projection beam scans over the patterning device in a given reference direction (the “scanning” direction) while synchronously moving the substrate parallel or anti-parallel to this reference direction. Different portions of the pattern on the patterning device are transferred to one target portion progressively.

Prior to transferring the pattern from the patterning device to the substrate, the substrate may undergo various procedures, such as priming, resist coating, and a soft bake. After exposure, the substrate may be subjected to other procedures (“post-exposure procedures”), such as a post-exposure bake (PEB), development, a hard bake and measurement/inspection of the transferred pattern. This array of procedures is used as a basis to make an individual layer of a device, e.g., an IC. The substrate may then undergo various processes such as etching, ion-implantation (doping), metallization, oxidation, deposition, chemo-mechanical polishing, etc., all intended to finish the individual layer of the device. If several layers are required in the device, then the whole procedure, or a variant thereof, is repeated for each layer. Eventually, a device will be present in each target portion on the substrate. These devices are then separated from one another by a technique such as dicing or sawing, such that the individual devices can be mounted on a carrier, connected to pins, etc.

Thus, manufacturing devices, such as semiconductor devices, typically involves processing a substrate (e.g., a semiconductor wafer) using a number of fabrication processes to form various features and multiple layers of the devices. Such layers and features are typically manufactured and processed using, e.g., deposition, lithography, etch, deposition, chemical-mechanical polishing, and ion implantation. Multiple devices may be fabricated on a plurality of dies on a substrate and then separated into individual devices. This device manufacturing process may be considered a patterning process. A patterning process involves a patterning step, such as optical and/or nanoimprint lithography using a patterning device in a lithographic apparatus, to transfer a pattern on the patterning device to a substrate and typically, but optionally, involves one or more related pattern processing steps, such as resist development by a development apparatus, baking of the substrate using a bake tool, etching using the pattern using an etch apparatus, deposition, etc.

Lithography is a central step in the manufacturing of device such as ICs, where patterns formed on substrates define functional elements of the devices, such as microprocessors, memory chips, etc. Similar lithographic techniques are also used in the formation of flat panel displays, micro-electro mechanical systems (MEMS) and other devices.

As semiconductor manufacturing processes continue to advance, the dimensions of functional elements have continually been reduced while the number of functional elements, such as transistors, per device has been steadily increasing over decades, following a trend commonly referred to as “Moore's law.” At the current state of technology, layers of devices are manufactured using lithographic projection apparatuses that project a design layout onto a substrate using illumination from a deep-ultraviolet illumination source, creating individual functional elements having dimensions well below 100 nm, i.e. less than half the wavelength of the radiation from the illumination source (e.g., a 193 nm illumination source).

This process in which features with dimensions smaller than the classical resolution limit of a lithographic projection apparatus are printed, is commonly known as low-k₁ lithography, according to the resolution formula CD=k₁×λW/NA, where λ is the wavelength of radiation employed (currently in most cases 248 nm or 193 nm), NA is the numerical aperture of projection optics in the lithographic projection apparatus, CD is the “critical dimension”—generally the smallest feature size printed—and k₁ is an empirical resolution factor. In general, the smaller K₁ the more difficult it becomes to reproduce a pattern on the substrate that resembles the shape and dimensions planned by a designer in order to achieve particular electrical functionality and performance. To overcome these difficulties, sophisticated fine-tuning steps are applied to the lithographic projection apparatus, the design layout, or the patterning device. These include, for example, but are not limited to, optimization of NA and optical coherence settings, customized illumination schemes, use of phase shifting patterning devices, optical proximity correction (OPC, sometimes also referred to as “optical and process correction”) in the design layout, or other methods generally defined as “resolution enhancement techniques” (RET).

### SUMMARY

A positioning system (and related methods) for an optical element, such as an objective, of a metrology apparatus is described. Compared to prior systems, the design of the present system provides three dimensional (e.g., X, Y, and Z) motion of a lighter objective stage with repositioned dimensional (e.g., X, Y) actuators. Three degrees of freedom of movement are provided by separate, individual bases actuating the objective stage. The bases are configured to move the stage in the X, Y, and/or Z directions independently, at different times and/or simultaneously, to precisely position the objective (optical element) for metrology. Flexible supports between each base and the objective stage translate motion from a base to the objective stage through a stiff axial connection. However, the flexible supports provide a sufficiently compliant connection in non-axial directions to reduce or prevent undesired translation, rotation, and/or tilt of the objective stage.

According to an embodiment, a positioning system for an optical element of a metrology apparatus is provided. The positioning system comprises a stage and a positioner. The positioner comprises at least one flexible support coupled to the stage. The at least one flexible support is configured to be relatively stiff in an axial direction of the positioner, and relatively flexible in other directions. The positioner comprises a base coupled to the at least one flexible support. The base is configured to be actuated to move in the axial direction, and in turn move the stage. The positioner comprises a guide configured to couple the base to a frame of the metrology apparatus. The guide is configured to bend when the base is actuated.

In some embodiments, the positioning system comprises first, second, and third positioners coupled to the stage and configured to move the stage in X, Y, and Z directions respectively. The first, second, and third positioners may be configured to move the stage in the X, Y, and Z directions independently, at different times and/or simultaneously, to precisely position the optical element for metrology, the optical element supported by the stage.

In some embodiments, the first positioner comprises a single flexible support, the second positioner comprises two flexible supports, and the third positioner comprises at least three flexible supports. In some embodiments, the third positioner comprises four flexible supports positioned at or near four corresponding corners of the stage. In some embodiments, the single flexible support of the first positioner is located at or near a center of a first side edge of the stage. In some embodiments, the two flexible supports of the second positioner are located at or near opposite corners of a second side edge of the stage. The two flexible supports are configured to reduce or prevent undesired rotation of the stage. In some embodiments, the four flexible supports of the third positioner are coupled to a top surface of the stage and configured to reduce or prevent undesired rotation and/or tilt of the stage.

In some embodiments, the four flexible supports of the third positioner are positioned around a porro prism of the metrology apparatus.

In some embodiments, the optical element is an objective.

In some embodiments, the guide comprises two parallel flexible plates positioned on opposite sides of the base.

In some embodiments, the frame is a sensor frame of the metrology apparatus.

In some embodiments, a positioner is configured to move the optical element for overlay measurements. The overlay measurements may be for a semiconductor wafer, and may be made as part of a semiconductor manufacturing process.

In some embodiments, a positioner further comprises an actuator coupled to the base configured to move the base in the axial direction, and in turn move the stage and the optical element.

According to another embodiment, a metrology apparatus is provided. The metrology apparatus comprises a radiation source configured to generate radiation directed toward a prism component and an objective along an optical path. The metrology apparatus comprises a positioning system for the objective. The positioning system comprises a stage configured to support the objective; and first, second, and third positioners coupled to the stage and configured to move the stage in X, Y, and Z directions respectively. A positioner comprises at least one flexible support coupled to the stage. The at least one flexible support is configured to be relatively stiff in an axial direction of the positioner, and relatively flexible in other directions. The positioner comprises a base coupled to the at least one flexible support. The base configured to be actuated to move in the axial direction, and in turn move the stage and the objective to direct the radiation toward a target on a substrate. The positioner comprises a guide configured to couple the base to a frame of the metrology apparatus. The guide is configured to bend when the base is actuated, but remain coupled to the frame. The metrology apparatus comprises a detector. The detector is configured to receive diffracted and reflected radiation from the target and generate a detection signal.

In some embodiments, the metrology apparatus comprises a second positioning system. The second positioning system is configured to position a second objective to facilitate two simultaneous measurements on the same substrate. The second positioning system may be configured such that a distance from one objective to another in the metrology apparatus is about 48 mm, for example. In some embodiments, the metrology apparatus comprises third and fourth positioning systems configured to position third and fourth objectives, respectively, to facilitate two additional simultaneous measurements on a second substrate by the metrology apparatus.

According to another embodiment, a method for positioning an optical element of a metrology apparatus is provided. The method comprises: supporting the optical element with a stage; coupling at least one flexible support of a positioner to the stage, the at least one flexible support configured to be relatively stiff in an axial direction of the positioner, and relatively flexible in other directions; coupling a base of the positioner to the at least one flexible support, the base configured to be actuated to move in the axial direction, and in turn move the stage; coupling the base to a frame of the metrology apparatus with a guide of the positioner, the guide configured to bend when the base is actuated; and actuating the base to move in the axial direction to move the stage and position the optical element.

According to another embodiment, a method performed with a metrology apparatus is provided. The method comprises: generating, with a radiation source of the metrology apparatus, radiation directed toward a prism component and an objective along an optical path; supporting the objective with a stage of the metrology apparatus; moving the stage with first, second, and third positioners of a first positioning system of the metrology apparatus, the first, second, and third positioners coupled to the stage, and configured to move the stage in X, Y, and Z directions respectively; coupling at least one flexible support to the stage, the at least one flexible support configured to be relatively stiff in an axial direction of the positioner, and relatively flexible in other directions; coupling a base coupled to the at least one flexible support, the base configured to be actuated to move in the axial direction, and in turn move the stage and the objective to direct the radiation toward a target on a substrate; coupling, with a guide, the base to a frame of the metrology apparatus, the guide configured to bend when the base is actuated, but remain coupled to the frame; and receiving, with a detector, diffracted and reflected radiation from the target and generate a detection signal.

According to another embodiment, a metrology apparatus having a prism component and an objective is provided. The metrology apparatus comprises an objective positioning system. The objective positioning system comprises: an objective stage configured to support the objective; and first, second, and third objective positioners coupled to the objective stage and configured to move the objective stage in X, Y, and Z directions respectively. An objective positioner comprises: at least one flexible objective support coupled to the stage, the at least one flexible objective support configured to be relatively stiff in an axial direction of the objective positioner, and relatively flexible in other directions; an objective base coupled to the at least one flexible objective support, the objective base configured to be actuated to move in the axial direction, and in turn move the objective stage and the objective to direct the radiation toward a target on a substrate; and an objective guide configured to couple the objective base to a frame of the metrology apparatus, the objective guide configured to bend when the objective base is actuated, but remain coupled to the frame. The metrology apparatus comprises a prism positioning system. The prism positioning system comprises: a prism stage configured to support the prism component; and first and second prism positioners coupled to the prism stage and configured to move the prism stage in X and Y directions respectively. A prism positioner comprises: at least one flexible prism support coupled to the prism stage, the at least one flexible prism support configured to be relatively stiff in an axial direction of the prism positioner, and relatively flexible in other directions; a prism base coupled to the at least one flexible prism support, the prism base configured to be actuated to move in the axial direction, and in turn move the prism stage and the prism component to direct radiation toward a target on a substrate; and a prism guide configured to couple the prism base to the frame of the metrology apparatus, the prism guide configured to bend when the prism base is actuated, but remain coupled to the frame.

According to another embodiment, a method performed with a metrology apparatus having a prism component and an objective is provided. The method comprises: supporting the objective with an objective stage; and coupling first, second, and third objective positioners to the objective stage and moving the objective stage in X, Y, and Z directions respectively. An objective positioner comprises: at least one flexible objective support coupled to the stage, the at least one flexible objective support configured to be relatively stiff in an axial direction of the objective positioner, and relatively flexible in other directions; an objective base coupled to the at least one flexible objective support, the objective base configured to be actuated to move in the axial direction, and in turn move the objective stage and the objective to direct the radiation toward a target on a substrate; and an objective guide configured to couple the objective base to a frame of the metrology apparatus, the objective guide configured to bend when the objective base is actuated, but remain coupled to the frame. The method comprises supporting the prism component with a prism stage; and coupling first and second prism positioners to the prism stage and moving the prism stage in X and Y directions respectively. A prism positioner comprises: at least one flexible prism support coupled to the prism stage, the at least one flexible prism support configured to be relatively stiff in an axial direction of the prism positioner, and relatively flexible in other directions; a prism base coupled to the at least one flexible prism support, the prism base configured to be actuated to move in the axial direction, and in turn move the prism stage and the prism component to direct radiation toward a target on a substrate; and a prism guide configured to couple the prism base to the frame of the metrology apparatus, the prism guide configured to bend when the prism base is actuated, but remain coupled to the frame.

### BRIEF DESCRIPTION OF THE DRAWINGS

The above aspects and other aspects and features will become apparent to those ordinarily skilled in the art upon review of the following description of specific embodiments in conjunction with the accompanying figures.

FIG. 1 schematically depicts a lithography apparatus, according to an embodiment.

FIG. 2 schematically depicts an embodiment of a lithographic cell or cluster, according to an embodiment.

FIG. 3 schematically depicts an example inspection system, according to an embodiment.

FIG. 4 schematically depicts an example metrology technique, according to an embodiment.

FIG. 5 illustrates the relationship between a radiation illumination spot of an inspection system and a metrology target, according to an embodiment.

FIG. 6 illustrates an example metrology system configured for inspection of two substrates (supported by two corresponding wafer tables) using two optical axes, with two corresponding sensors, according to an embodiment.

FIG. 7 illustrates an example metrology system with two sets of positioning elements and optical components coupled to one central sensor, instead of two sensors, as shown in FIG. 6, according to an embodiment.

FIG. 8 illustrates a mechanical system configured to achieve desired motion of an objective included in a metrology system, according to an embodiment.

FIG. 9 illustrates a positioning system for an optical element such as an objective of a metrology apparatus, according to an embodiment.

FIG. 10 illustrates a metrology apparatus comprising a second positioning system, according to an embodiment.

FIG. 11 illustrates a metrology apparatus comprising third and fourth positioning systems, according to an embodiment.

FIG. 12 provides a perspective view of the metrology apparatus shown in FIG. 11, according to an embodiment.

FIG. 13 illustrates a metrology apparatus having a prism component and an objective, with corresponding prism and objective positioning systems, according to an embodiment.

FIG. 14 illustrates a metrology method, according to an embodiment.

FIG. 15 is a block diagram of an example computer system, according to an embodiment.

### DETAILED DESCRIPTION

In semiconductor device manufacturing, metrology operations typically include determining the position of a metrology mark (or marks) and/or other target in a layer of a semiconductor device structure. This position is typically determined by irradiating a metrology mark with radiation, and comparing characteristics of different diffraction orders of radiation reflected from the metrology mark. Such techniques are used to measure overlay, alignment, and/or other parameters.

Prior metrology systems are configured to move different objectives in different directions with respect to a central sensor. An objective typically includes multiple lenses supported in a housing. A double porro prism is often used for path length compensation in such systems. A double porro prism directs incoming light towards the objective. A porro prism typically moves in a 1:2 ratio with corresponding objective (e.g. XY direction) motion. A double porro prism comprises two porro prisms, where a single porro prims comprises two reflecting surfaces under an angle of 90 degrees. The porro prisms are rotated 90 degrees around a z-axis with respect to each other. Each porro prism compensates the path length and provides beam steering in one degree of freedom, e.g., X or Y. Mechanical coupling of the double porro prism motion is coupled to the objective's motion in these systems by a connection at a half-length of certain (e.g., XY direction) flexures, while a first dimensional (e.g., a Z direction) actuator is connected in series to other dimensional (e.g., XY) actuators to move the entire porro prism and objective system to focus radiation on a target on a substrate. This design has a large moving mass in the Z direction due to the XY actuators and the porro prism. Lorenz motors included in such systems are inefficient due to a required spacing between coils and magnets to allow Z direction motion. In addition, there is increased thermal loading of the objective due to the proximity of the XY actuators, there is an inability to provide sufficient prism positioning due to inherent inefficiencies of the XY flexures, an additional external fine alignment method is required to center radiation over the objective, and multiple pitch distances (>2×) between objectives are required for simultaneous measurements on a single substrate.

Advantageously, the present system(s) and method(s) provide an improved positioning system for an optical element, such as an objective, of a metrology apparatus. Compared to prior systems, the design of the present system provides three dimensional (e.g., X, Y, and Z) motion of a lighter objective stage with repositioned dimensional (e.g., X, Y) actuators. Three degrees of freedom of movement are provided by separate, individual bases actuating the objective stage. The bases are configured to move the stage in the X, Y, and/or Z directions independently, at different times and/or simultaneously, to precisely position the objective (optical element) for metrology. Flexible supports between each base and the objective stage translate motion from a base to the objective stage through a stiff axial connection. However, the flexible supports provide a sufficiently compliant connection in non-axial directions to reduce or prevent undesired translation, rotation, and/or tilt of the objective stage. This reduces the moving mass in the Z direction, reduces the required spacing between actuator coils and magnets to allow Z direction motion, decreases thermal loading of the objective, provides sufficient prism positioning, does not require an external fine alignment method to center radiation over the objective, and multiple pitch distances between objectives are not required for simultaneous measurements on a single substrate.

By way of a brief introduction, the description below relates to semiconductor device manufacturing and patterning processes. The following paragraphs also describe several components of systems and/or methods for semiconductor device metrology. These systems and methods may be used for measuring overlay, alignment, etc., in a semiconductor device manufacturing process, for example, or for other operations.

Although specific reference may be made in this text to the measurement of overlay, alignment, or other parameters, and the manufacture of integrated circuits (ICs) for semiconductor devices, it should be understood that the description herein has many other possible applications. For example, it may be employed in the manufacture of integrated optical systems, guidance and detection patterns for magnetic domain memories, liquid-crystal display panels, thin-film magnetic heads, etc. The skilled artisan will appreciate that, in the context of such alternative applications, any use of the terms “reticle,” “wafer” or “die” in this text should be considered as interchangeable with the more general terms “mask,” “substrate” and “target portion,” respectively.

The term “projection optics” as used herein should be broadly interpreted as encompassing various types of optical systems, including refractive optics, reflective optics, apertures and catadioptric optics, for example. The term “projection optics” may also include components operating according to any of these design types for directing, shaping or controlling the projection beam of radiation, collectively or singularly. The term “projection optics” may include any optical component in the lithographic projection apparatus, no matter where the optical component is located on an optical path of the lithographic projection apparatus. Projection optics may include optical components for shaping, adjusting and/or projecting radiation from the source before the radiation passes the patterning device, and/or optical components for shaping, adjusting and/or projecting the radiation after the radiation passes the patterning device. The projection optics generally exclude the source and the patterning device.

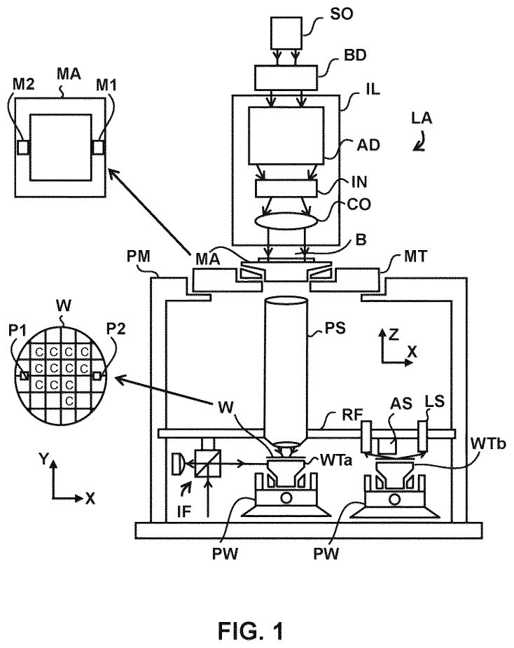

FIG. 1 schematically depicts an embodiment of a lithographic apparatus LA. The apparatus comprises an illumination system (illuminator) IL configured to condition a radiation beam B (e.g. UV radiation, DUV radiation, or EUV radiation); a support structure (e.g. a mask table) MT constructed to support a patterning device (e.g. a mask) MA and connected to a first positioner PM configured to accurately position the patterning device in accordance with certain parameters; a substrate table (e.g. a wafer table) WT (e.g., WTa, WTb or both) configured to hold a substrate (e.g. a resist-coated wafer) W and coupled to a second positioner PW configured to accurately position the substrate in accordance with certain parameters; and a projection system (e.g. a refractive projection lens system) PS configured to project a pattern imparted to the radiation beam B by patterning device MA onto a target portion C (e.g. comprising one or more dies and often referred to as fields) of the substrate W. The projection system is supported on a reference frame RF. As depicted, the apparatus is of a transmissive type (e.g. employing a transmissive mask). Alternatively, the apparatus may be of a reflective type (e.g. employing a programmable mirror array, or employing a reflective mask).

The illuminator IL receives a beam of radiation from a radiation source SO. The source and the lithographic apparatus may be separate entities, for example when the source is an excimer laser. In such cases, the source is not considered to form part of the lithographic apparatus and the radiation beam is passed from the source SO to the illuminator IL with the aid of a beam delivery system BD comprising for example suitable directing mirrors and/or a beam expander. In other cases, the source may be an integral part of the apparatus, for example when the source is a mercury lamp. The source SO and the illuminator IL, together with the beam delivery system BD if required, may be referred to as a radiation system.

The illuminator IL may alter the intensity distribution of the beam. The illuminator may be arranged to limit the radial extent of the radiation beam such that the intensity distribution is non-zero within an annular region in a pupil plane of the illuminator IL. Additionally or alternatively, the illuminator IL may be operable to limit the distribution of the beam in the pupil plane such that the intensity distribution is non-zero in a plurality of equally spaced sectors in the pupil plane. The intensity distribution of the radiation beam in a pupil plane of the illuminator IL may be referred to as an illumination mode.

The illuminator IL may comprise adjuster AD configured to adjust the (angular/spatial) intensity distribution of the beam. Generally, at least the outer and/or inner radial extent (commonly referred to as σ-outer and σ-inner, respectively) of the intensity distribution in a pupil plane of the illuminator can be adjusted. The illuminator IL may be operable to vary the angular distribution of the beam. For example, the illuminator may be operable to alter the number, and angular extent, of sectors in the pupil plane wherein the intensity distribution is non-zero. By adjusting the intensity distribution of the beam in the pupil plane of the illuminator, different illumination modes may be achieved. For example, by limiting the radial and angular extent of the intensity distribution in the pupil plane of the illuminator IL, the intensity distribution may have a multi-pole distribution such as, for example, a dipole, quadrupole or hexapole distribution. A desired illumination mode may be obtained, e.g., by inserting an optic which provides that illumination mode into the illuminator IL or using a spatial light modulator.

The illuminator IL may be operable to alter the polarization of the beam and may be operable to adjust the polarization using adjuster AD. The polarization state of the radiation beam across a pupil plane of the illuminator IL may be referred to as a polarization mode. The use of different polarization modes may allow greater contrast to be achieved in the image formed on the substrate W. The radiation beam may be unpolarized. Alternatively, the illuminator may be arranged to linearly polarize the radiation beam. The polarization direction of the radiation beam may vary across a pupil plane of the illuminator IL. The polarization direction of radiation may be different in different regions in the pupil plane of the illuminator IL. The polarization state of the radiation may be chosen in dependence on the illumination mode. For multi-pole illumination modes, the polarization of each pole of the radiation beam may be generally perpendicular to the position vector of that pole in the pupil plane of the illuminator IL. For example, for a dipole illumination mode, the radiation may be linearly polarized in a direction that is substantially perpendicular to a line that bisects the two opposing sectors of the dipole. The radiation beam may be polarized in one of two different orthogonal directions, which may be referred to as X-polarized and Y-polarized states. For a quadrupole illumination mode, the radiation in the sector of each pole may be linearly polarized in a direction that is substantially perpendicular to a line that bisects that sector. This polarization mode may be referred to as XY polarization. Similarly, for a hexapole illumination mode the radiation in the sector of each pole may be linearly polarized in a direction that is substantially perpendicular to a line that bisects that sector. This polarization mode may be referred to as TE polarization.

In addition, the illuminator IL generally comprises various other components, such as an integrator IN and a condenser CO. The illumination system may include various types of optical components, such as refractive, reflective, magnetic, electromagnetic, electrostatic or other types of optical components, or any combination thereof, for directing, shaping, or controlling radiation. Thus, the illuminator provides a conditioned beam of radiation B, having a desired uniformity and intensity distribution in its cross section.

The support structure MT supports the patterning device in a manner that depends on the orientation of the patterning device, the design of the lithographic apparatus, and other conditions, such as for example whether or not the patterning device is held in a vacuum environment. The support structure may use mechanical, vacuum, electrostatic or other clamping techniques to hold the patterning device. The support structure may be a frame or a table, for example, which may be fixed or movable as required. The support structure may ensure that the patterning device is at a desired position, for example with respect to the projection system. Any use of the terms “reticle” or “mask” herein may be considered synonymous with the more general term “patterning device.”

The term “patterning device” used herein should be broadly interpreted as referring to any device that can be used to impart a pattern in a target portion of the substrate. In an embodiment, a patterning device is any device that can be used to impart a radiation beam with a pattern in its cross-section to create a pattern in a target portion of the substrate. It should be noted that the pattern imparted to the radiation beam may not exactly correspond to the desired pattern in the target portion of the substrate, for example if the pattern includes phase-shifting features or so called assist features. Generally, the pattern imparted to the radiation beam will correspond to a particular functional layer in a device being created in a target portion of the device, such as an integrated circuit.

A patterning device may be transmissive or reflective. Examples of patterning devices include masks, programmable mirror arrays, and programmable LCD panels. Masks are well known in lithography, and include mask types such as binary, alternating phase-shift, and attenuated phase-shift, as well as various hybrid mask types. An example of a programmable mirror array employs a matrix arrangement of small mirrors, each of which can be individually tilted to reflect an incoming radiation beam in different directions. The tilted mirrors impart a pattern in a radiation beam, which is reflected by the mirror matrix.

The term “projection system” should be broadly interpreted as encompassing any type of projection system, including refractive, reflective, catadioptric, magnetic, electromagnetic and electrostatic optical systems, or any combination thereof, as appropriate for the exposure radiation being used, or for other factors such as the use of an immersion liquid or the use of a vacuum. Any use of the term “projection lens” herein may be considered as synonymous with the more general term “projection system.”

The projection system PS may comprise a plurality of optical (e.g., lens) elements and may further comprise an adjustment mechanism configured to adjust one or more of the optical elements to correct for aberrations (phase variations across the pupil plane throughout the field). To achieve this, the adjustment mechanism may be operable to manipulate one or more optical (e.g., lens) elements within the projection system PS in one or more different ways. The projection system may have a coordinate system wherein its optical axis extends in the z direction. The adjustment mechanism may be operable to do any combination of the following: displace one or more optical elements; tilt one or more optical elements; and/or deform one or more optical elements. Displacement of an optical element may be in any direction (x, y, z, or a combination thereof). Tilting of an optical element is typically out of a plane perpendicular to the optical axis, by rotating about an axis in the x and/or y directions although a rotation about the z axis may be used for a non-rotationally symmetric aspherical optical element. Deformation of an optical element may include a low frequency shape (e.g. astigmatic) and/or a high frequency shape (e.g. free form aspheres). Deformation of an optical element may be performed for example by using one or more actuators to exert force on one or more sides of the optical element and/or by using one or more heating elements to heat one or more selected regions of the optical element. In general, it may not be possible to adjust the projection system PS to correct for apodization (transmission variation across the pupil plane). The transmission map of a projection system PS may be used when designing a patterning device (e.g., mask) MA for the lithography apparatus LA. Using a computational lithography technique, the patterning device MA may be designed to at least partially correct for apodization.

The lithographic apparatus may be of a type having two (dual stage) or more tables (e.g., two or more substrate tables WTa, WTb, two or more patterning device tables, a substrate table WTa and a table WTb below the projection system without a substrate that is dedicated to, for example, facilitating measurement, and/or cleaning, etc.). In such “multiple stage” machines, the additional tables may be used in parallel, or preparatory steps may be conducted on one or more tables while one or more other tables are being used for exposure. For example, alignment measurements using an alignment sensor AS and/or level (height, tilt, etc.) measurements using a level sensor LS may be made.

The lithographic apparatus may also be of a type wherein at least a portion of the substrate may be covered by a liquid having a relatively high refractive index, e.g. water, to fill a space between the projection system and the substrate. An immersion liquid may also be applied to other spaces in the lithographic apparatus, for example, between the patterning device and the projection system. Immersion techniques are well known in the art for increasing the numerical aperture of projection systems. The term “immersion” as used herein does not mean that a structure, such as a substrate, must be submerged in liquid, but rather only means that liquid is located between the projection system and the substrate during exposure.

In operation of the lithographic apparatus, a radiation beam is conditioned and provided by the illumination system IL. The radiation beam B is incident on the patterning device (e.g., mask) MA, which is held on the support structure (e.g., mask table) MT, and is patterned by the patterning device. Having traversed the patterning device MA, the radiation beam B passes through the projection system PS, which focuses the beam onto a target portion C of the substrate W. With the aid of the second positioner PW and position sensor IF (e.g. an interferometric device, linear encoder, 2-D encoder or capacitive sensor), the substrate table WT can be moved accurately, e.g. to position different target portions C in the path of the radiation beam B. Similarly, the first positioner PM and another position sensor (which is not explicitly depicted in FIG. 1) can be used to accurately position the patterning device MA with respect to the path of the radiation beam B, e.g. after mechanical retrieval from a mask library, or during a scan. In general, movement of the support structure MT may be realized with the aid of a long-stroke module (coarse positioning) and a short-stroke module (fine positioning), which form part of the first positioner PM. Similarly, movement of the substrate table WT may be realized using a long-stroke module and a short-stroke module, which form part of the second positioner PW. In the case of a stepper (as opposed to a scanner), the support structure MT may be connected to a short-stroke actuator only, or may be fixed. Patterning device MA and substrate W may be aligned using patterning device alignment marks M1, M2 and substrate alignment marks P1, P2. Although the substrate alignment marks as illustrated occupy dedicated target portions, they may be located in spaces between target portions (these are known as scribe-lane alignment marks). Similarly, in situations in which more than one die is provided on the patterning device MA, the patterning device alignment marks may be located between the dies.

The depicted apparatus may be used in at least one of the following modes. In step mode, the support structure MT and the substrate table WT are kept essentially stationary, while a pattern imparted to the radiation beam is projected onto a target portion C at one time (i.e. a single static exposure). The substrate table WT is then shifted in the X and/or Y direction so that a different target portion C can be exposed. In step mode, the maximum size of the exposure field limits the size of the target portion C imaged in a single static exposure. In scan mode, the support structure MT and the substrate table WT are scanned synchronously while a pattern imparted to the radiation beam is projected onto a target portion C (i.e. a single dynamic exposure). The velocity and direction of the substrate table WT relative to the support structure MT may be determined by the (de-)magnification and image reversal characteristics of the projection system PS. In scan mode, the maximum size of the exposure field limits the width (in the non-scanning direction) of the target portion in a single dynamic exposure, whereas the length of the scanning motion determines the height (in the scanning direction) of the target portion. In another mode, the support structure MT is kept essentially stationary holding a programmable patterning device, and the substrate table WT is moved or scanned while a pattern imparted to the radiation beam is projected onto a target portion C. In this mode, generally a pulsed radiation source is employed, and the programmable patterning device is updated as required after each movement of the substrate table WT or in between successive radiation pulses during a scan. This mode of operation can be readily applied to maskless lithography that utilizes programmable patterning device, such as a programmable mirror array of a type as referred to above.

Combinations and/or variations on the above-described modes of use or entirely different modes of use may also be employed.

The substrate may be processed, before or after exposure, in for example a track (a tool that typically applies a layer of resist to a substrate and develops the exposed resist) or a metrology or inspection tool. Where applicable, the disclosure herein may be applied to such and other substrate processing tools. Further, the substrate may be processed more than once, for example in order to create a multi-layer IC, so that the term substrate used herein may also refer to a substrate that already includes multiple processed layers.

The terms “radiation” and “beam” used herein with respect to lithography encompass all types of electromagnetic radiation, including ultraviolet (UV) or deep ultraviolet (DUV) radiation (e.g. having a wavelength of 365, 248, 193, 157 or 126 nm) and extreme ultra-violet (EUV) radiation (e.g. having a wavelength in the range of 5-20 nm), as well as particle beams, such as ion beams or electron beams.

Various patterns on or provided by a patterning device may have different process windows. i.e., a space of processing variables under which a pattern will be produced within specification. Examples of pattern specifications that relate to potential systematic defects include checks for necking, line pull back, line thinning, CD, edge placement, overlapping, resist top loss, resist undercut and/or bridging. The process window of the patterns on a patterning device or an area thereof may be obtained by merging (e.g., overlapping) process windows of each individual pattern. The boundary of the process window of a group of patterns comprises boundaries of process windows of some of the individual patterns. In other words, these individual patterns limit the process window of the group of patterns.

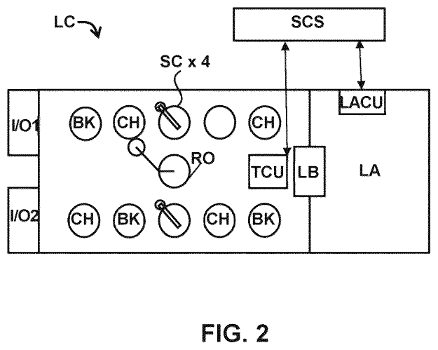

As shown in FIG. 2, the lithographic apparatus LA may form part of a lithographic cell LC, also sometimes referred to a lithocell or cluster, which also includes apparatuses to perform pre-and post-exposure processes on a substrate. Conventionally these include one or more spin coaters SC to deposit one or more resist layers, one or more developers to develop exposed resist, one or more chill plates CH and/or one or more bake plates BK. A substrate handler, or robot, RO picks up one or more substrates from input/output port I/O1, I/O2, moves them between the different process apparatuses and delivers them to the loading bay LB of the lithographic apparatus. These apparatuses, which are often collectively referred to as the track, are under the control of a track control unit TCU which is itself controlled by the supervisory control system SCS, which also controls the lithographic apparatus via lithography control unit LACU. Thus, the different apparatuses can be operated to maximize throughput and processing efficiency.

In order that a substrate that is exposed by the lithographic apparatus is exposed correctly and consistently and/or in order to monitor a part of the patterning process (e.g., a device manufacturing process) that includes at least one pattern transfer step (e.g., an optical lithography step), it is desirable to inspect a substrate or other object to measure or determine one or more properties such as alignment, overlay (which can be, for example, between structures in overlying layers or between structures in a same layer that have been provided separately to the layer by, for example, a double patterning process), line thickness, critical dimension (CD), focus offset, a material property, etc. Accordingly, a manufacturing facility in which lithocell LC is located also typically includes a metrology system that measures some or all of the substrates W (FIG. 1) that have been processed in the lithocell or other objects in the lithocell. The metrology system may be part of the lithocell LC, for example it may be part of the lithographic apparatus LA (such as alignment sensor AS (FIG. 1)).

The one or more measured parameters may include, for example, alignment, overlay between successive layers formed in or on the patterned substrate, critical dimension (CD) (e.g., critical linewidth) of, for example, features formed in or on the patterned substrate, focus or focus error of an optical lithography step, dose or dose error of an optical lithography step, optical aberrations of an optical lithography step, etc. This measurement is often performed on one or more dedicated metrology targets provided on the substrate. The measurement can be performed after-development of a resist but before etching, after-etching, after deposition, and/or at other times.

There are various techniques for making measurements of the structures formed in the patterning process, including the use of a scanning electron microscope, an image-based measurement tool and/or various specialized tools. A fast and non-invasive form of specialized metrology tool is one in which a beam of radiation is directed onto a target on the surface of the substrate and properties of the scattered (diffracted/reflected) beam are measured. By evaluating one or more properties of the radiation scattered by the substrate, one or more properties of the substrate can be determined. Traditionally, this may be termed diffraction-based metrology. Applications of this diffraction-based metrology include the measurement of overlay, alignment, etc. For example, overlay and/or alignment can be measured by comparing parts of the diffraction spectrum (for example, comparing different diffraction orders in the diffraction spectrum of a periodic grating).

Thus, in a device fabrication process (e.g., a patterning process or a lithography process), a substrate or other objects may be subjected to various types of measurement during or after the process. The measurement may determine whether a particular substrate is defective, may establish adjustments to the process and apparatuses used in the process (e.g., aligning two layers on the substrate or aligning the patterning device to the substrate), may measure the performance of the process and the apparatuses, or may be for other purposes. Examples of measurement include optical imaging (e.g., optical microscope), non-imaging optical measurement (e.g., measurement based on diffraction such as the ASML YieldStar metrology tool, the ASML SMASH metrology system), mechanical measurement (e.g., profiling using a stylus, atomic force microscopy (AFM)), and/or non-optical imaging (e.g., scanning electron microscopy (SEM)). U.S. Pat. No. 6,961,116, which is incorporated by reference herein in its entirety, describes a self-referencing interferometer that produces two overlapping and relatively rotated images of an alignment marker, detects intensities in a pupil plane where Fourier transforms of the images are caused to interfere, and extracts the positional information from the phase difference between diffraction orders of the two images which manifests as intensity variations in the interfered orders.

Metrology results may be provided directly or indirectly to the supervisory control system SCS. If an error is detected, an adjustment may be made to exposure of a subsequent substrate (especially if the inspection can be done soon and fast enough that one or more other substrates of the batch are still to be exposed) and/or to subsequent exposure of the exposed substrate. Also, an already exposed substrate may be stripped and reworked to improve yield, or discarded, thereby avoiding performing further processing on a substrate known to be faulty. In a case where only some target portions of a substrate are faulty, further exposures may be performed only on those target portions which meet specifications. Other manufacturing process adjustments are contemplated.

A metrology system may be used to determine one or more properties of the substrate structure, and in particular, how one or more properties of different substrate structures vary, or different layers of the same substrate structure vary from layer to layer. The metrology system may be integrated into the lithographic apparatus LA or the lithocell LC, or may be a stand-alone device.

To enable the metrology, often one or more targets are specifically provided on the substrate. Typically, the target is specially designed and may comprise a periodic structure. For example, the target on a substrate may comprise one or more 1-D periodic structures (e.g., geometric features such as gratings), which are printed such that after development, the periodic structural features are formed of solid resist lines. As another example, the target may comprise one or more 2-D periodic structures (e.g., gratings), which are printed such that after development, the one or more periodic structures are formed of solid resist pillars or vias in the resist. The bars, pillars, or vias may alternatively be etched into the substrate (e.g., into one or more layers on the substrate).

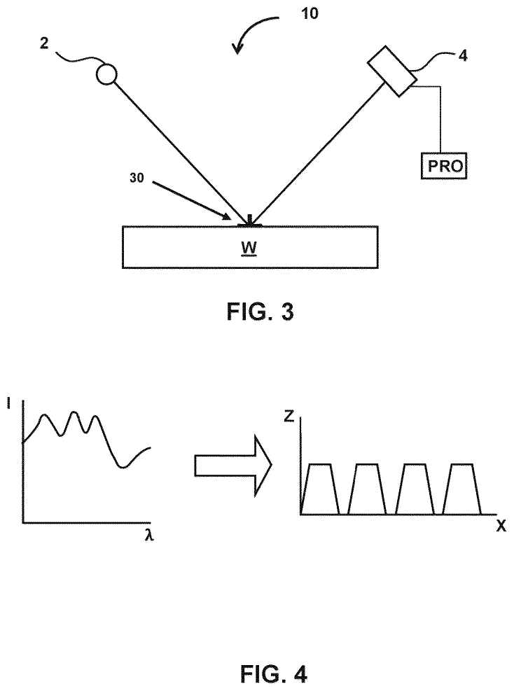

FIG. 3 depicts an example metrology (inspection) system 10 that may be used to detect overlay, alignment, and/or perform other metrology operations. It comprises a radiation or illumination source 2 which projects or otherwise irradiates radiation onto a substrate W (e.g., which may typically include a metrology mark). The redirected radiation is passed to a sensor such as a spectrometer detector 4 and/or other sensors, which measures a spectrum (intensity as a function of wavelength) of the specular reflected and/or diffracted radiation, as shown, e.g., in the graph on the left of FIG. 4. The sensor may generate a metrology signal conveying metrology data indicative of properties of the reflected radiation. From this data, the structure or profile giving rise to the detected spectrum may be reconstructed by one or more processors PRO, a generalized example of which is shown in FIG. 4, or by other operations.

As in the lithographic apparatus LA in FIG. 1, one or more substrate tables (not shown in FIG. 4) may be provided to hold the substrate W during measurement operations. The one or more substrate tables may be similar or identical in form to the substrate table WT (WTa or WTb or both) of FIG. 1. In an example where inspection system 10 is integrated with the lithographic apparatus, they may even be the same substrate table. Coarse and fine positioners may be provided and configured to accurately position the substrate in relation to a measurement optical system. Various sensors and actuators are provided, for example, to acquire the position of a target portion of interest of a structure (e.g., a metrology mark), and to bring it into position under an objective (lens). Typically, many measurements will be made on target portions of a structure at different locations across the substrate W. The objective and/or the substrate support can be moved in X and Y directions to acquire different targets, and in the Z direction to obtain a desired location of the target portion relative to the focus of the optical system. It is convenient to think and describe operations as if the objective lens is being brought to different locations relative to the substrate. Provided the relative position of the substrate and the optical system is correct, it does not matter in principle which one of the objective and/or substrate is moving, or if both are moving, or a combination of a part of the optical system is moving (e.g., in the Z and/or tilt direction) with the remainder of the optical system being stationary and the substrate is moving (e.g., in the X and Y directions, but also optionally in the Z and/or tilt direction).

For typical metrology measurements, a target (portion) 30 on substrate W may be a 1-D grating, which is printed such that after development, the bars are formed of solid resist lines (e.g., which may be covered by a deposition layer), and/or other materials. Or the target 30 may be a 2-D grating, which is printed such that after development, the grating is formed of solid resist pillars, and/or other features in the resist.

The bars, pillars, vias, and/or other features may be etched into or on the substrate (e.g., into one or more layers on the substrate), deposited on a substrate, covered by a deposition layer, and/or have other properties. Target (portion) 30 (e.g., of bars, pillars, vias, etc.) is sensitive to changes in processing in the patterning process (e.g., optical aberration in the lithographic projection apparatus such as in the projection system, focus change, dose change, etc.) such that process variation manifests in variation in target 30. Accordingly, the measured data from target 30 may be used to determine an adjustment for one or more of the manufacturing processes, and/or used as a basis for making the actual adjustment.

For example, the measured data from target 30 may indicate overlay for a layer of a semiconductor device. The measured data from target 30 may be used (e.g., by the one or more processors PRO and/or other processors) for determining one or more semiconductor device manufacturing process parameters based the overlay, and determining an adjustment for a semiconductor device manufacturing apparatus based on the one or more determined semiconductor device manufacturing process parameters. In some embodiments, this may comprise a stage position adjustment, for example, or this may include determining an adjustment for a mask design, a metrology target design, a semiconductor device design, an intensity of the radiation, an incident angle of the radiation, a wavelength of the radiation, a pupil size and/or shape, a resist material, and/or other process parameters.

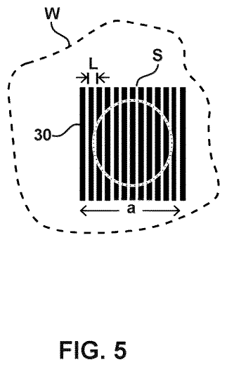

FIG. 5 illustrates a plan view of a typical target (e.g., metrology mark) 30, and the extent of a typical radiation illumination spot S in the system of FIG. 4. Typically, to obtain a diffraction spectrum that is free of interference from surrounding structures, the target 30, in an embodiment, is a periodic structure (e.g., grating) larger than the width (e.g., diameter) of the illumination spot S. The width of spot S may be smaller than the width and length of the target. The target, in other words, is ‘underfilled’ by the illumination, and the diffraction signal is essentially free from any signals from product features and the like outside the target itself. The illumination arrangement may be configured to provide illumination of a uniform intensity across a back focal plane of an objective, for example. Alternatively, by, for example, including an aperture in the illumination path, illumination may be restricted to on axis or off axis directions.

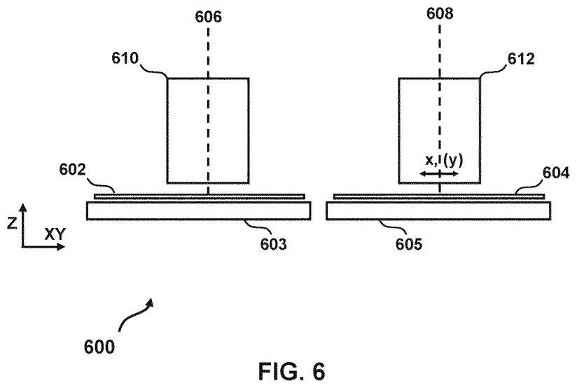

FIG. 6 illustrates an example metrology system 600 configured for inspection of two substrates (wafers) 602 and 604 (supported by two corresponding wafer tables 603 and 605) using two optical axes 606 and 608, with two corresponding sets of optical components and positioning elements (not shown in FIG. 6) and sensors 610 and 612. A wafer table 603 and/or 605 in such a system typically has only four degrees of freedom (X, Y, ΔY, Rz). Therefore, a positioning system for second sensor 612 needs at least an X axis (in this example) degree of freedom (relative to a positioning system for first sensor 610) to accommodate for ΔX error between two substrates (wafers) 602 and 604. A second degree of freedom (e.g., a Y axis degree of freedom) for the positioning system of second sensor 612 may also be advantageous.

Note that the descriptions of different axes provided herein (e.g., X, Y, and Z axes) are intended to provide the reader a clearer understanding of the described system(s), without limiting components of such systems to the specific axes, directions, etc., shown in a particular figure. The different axes are described relative to each other, to give the reader an understanding of how one component is positioned relative to another. Axes such as X, Y, and Z axis could easily be replaced by first, second, and third axes, for example, and/or the coordinate system in a given figure could easily be rotated one direction or another (e.g., so that certain components then lie on a Y axis instead of an X axis, etc.), without changing the described system(s) themselves.

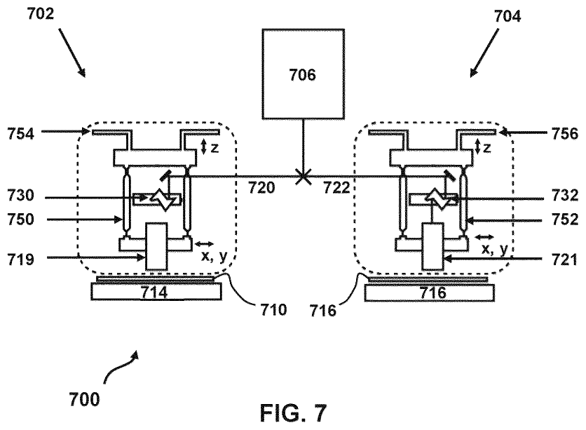

FIG. 7 illustrates an example metrology system 700 with two sets of positioning elements and optical components 702 and 704 coupled to one central sensor 706, instead of two sensors, as shown in FIG. 6. Substrates 710 and 712, and corresponding wafer tables 714 and 716 are also illustrated. FIG. 7 illustrates central sensor 706 relative to two optical component objective 719 and objective 721 branches 720 and 722 formed using two porro prisms 730 and 732 (e.g., a double porro prism system). Each objective 719 and 721 is configured to move in the X/Y directions with respect to central sensor 706. This is achieved with the double porro prism system, which is used for path length compensation as shown in FIG. 7. Directional flexible supports (e.g., XY directional flexible supports 750 and 752, and Z directional flexible supports 754 and 756) are used to reduce or prevent undesired movement (e.g., unwanted XY movement when an objective is moved in a Z direction, unwanted Z movement when an objective is moved in an X or Y direction, etc.) of objectives 719 and 721, respectively.

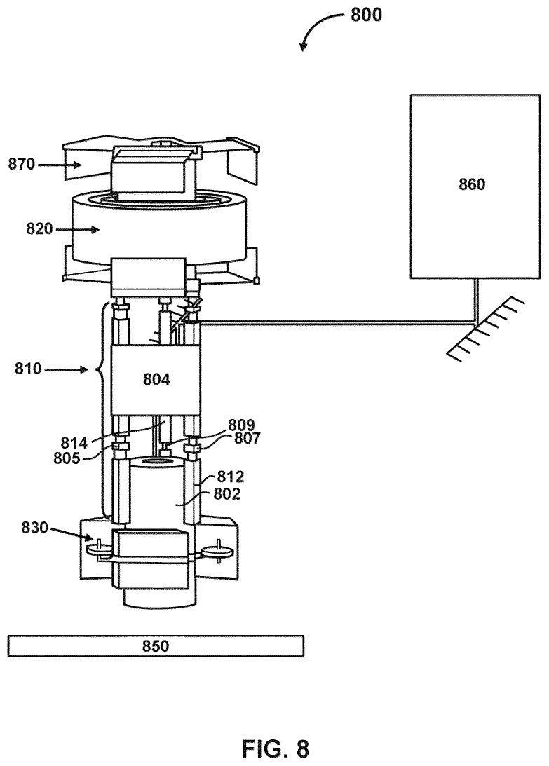

FIG. 8 illustrates a mechanical system 800 configured to achieve desired motion of an objective 802 included in a metrology system. In system 800, motion of a double porro prism 804 is coupled to the motion of objective 802 by connections 805, 807, 809 at approximately half-lengths of XY flexible supports 810, 812, and 814. As shown in FIG. 8, system 800 includes a Z actuator 820 connected in series to an XY actuator 830 to move objective 802 for focusing radiation on a substrate. FIG. 8 also illustrates a substrate 850, a central sensor 860, a Z flexure 870, and other components.

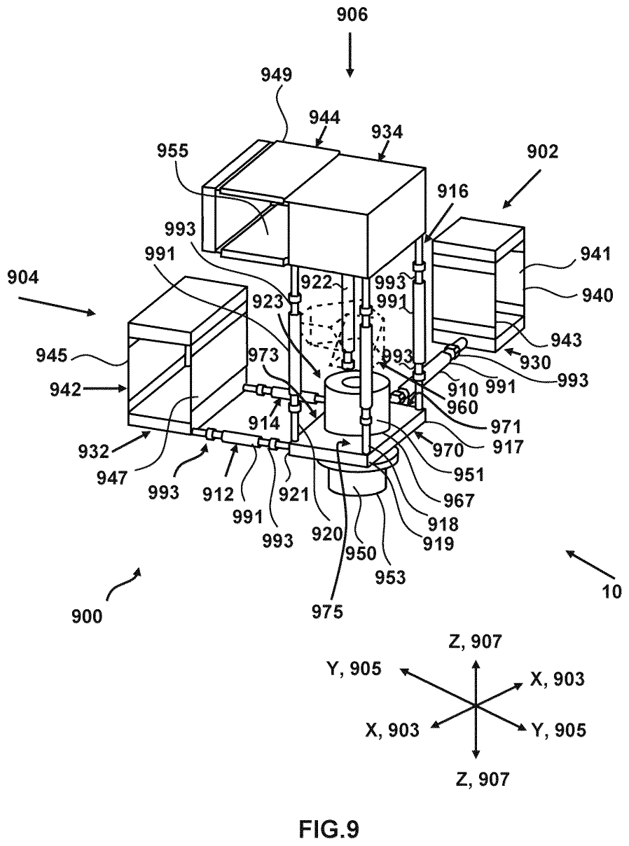

FIG. 9 illustrates a positioning system 900 for an optical element such as an objective 950 of a metrology apparatus (e.g., system 10 shown in FIG. 3). The metrology apparatus uses radiation to obtain information from metrology targets, and/or for other uses. Radiation may comprise illumination such as light and/or other radiation. A target (such as target 30 described above) may comprise one or more metrology marks, such as diffraction grating targets, formed in a substrate such as a semiconductor wafer, for example. A target may be one or more metrology marks such as diffraction grating targets on a semiconductor wafer, as described herein, for example, collectively referred to as a single target. A target may comprise one or more structures in the patterned substrate capable of providing a diffraction signal. One or more targets may be included in a layer of a substrate in a semiconductor device structure, for example. In some embodiments, a target comprises a geometric feature such as a 1D or 2D feature, and/or other geometric features. By way of several non-limiting examples, a target may comprise a grating, a line, an edge, a fine-pitched series of lines and/or edges, and/or other features.

Positioning system 900 may form a portion of system 10 described above with respect to FIG. 3. Positioning system 900 may be a subsystem of system 10, for example. In some embodiments, one or more components of positioning system 900 may be similar to and/or the same as one or more components of system 10. In some embodiments, one or more components of positioning system 900 may replace, be used with, and/or otherwise augment one or more components of system 10.

Positioning system 900 provides a new design architecture compared to prior systems (e.g., relative to the systems shown in FIGS. 6, 7, and 8). Instead of mechanically coupling motion of a porro prism to an objective's motion by a connection at a half-length of certain (e.g., XY direction) flexures, while a first dimensional (e.g., a Z direction) actuator is connected in series to other dimensional (e.g., XY) actuators to move the entire porro prism and objective system to focus radiation on a target on a substrate, system 900 provides three dimensional (e.g., X, Y, and Z) motion of a lighter objective stage with repositioned dimensional (e.g., X, Y) actuators. Positioning system 900 comprises a stage 970, a positioner such as positioners 902, 904, and/or 906, and/or other components. Positioners 902, 904, and/or 906 may be configured to move objective 950 (e.g., the optical element) for overlay measurements, for example. The overlay measurements may be for a semiconductor wafer (e.g., a substrate), and may be made as part of a semiconductor manufacturing process (e.g., as described above).

Objective 950 (the optical element) is supported by stage 970. Objective 950 may comprise one or more lenses formed from any transparent material that have curved surfaces configured to concentrate or otherwise focus one or more spots of radiation on substrate target(s) (as described above). Stage 970 may support objective 950 by holding objective 950, being coupled to objective 950, surrounding objective 950, and/or supporting objective 950 in other ways. In some embodiments, objective 950 may be coupled to stage 970 via structural members, clips, clamps, screws, nuts, bolts, adhesive, and/or other mechanical devices. For example, as shown in FIG. 9, stage 970 may have a rectangular prism shape (having a length, width, and thickness configured to be compatible with the other components of positioning system 900 and/or metrology system 10) with a cylindrically shaped orifice 967 at or near a center of a top surface 975 of stage 970. Orifice 967 is configured to receive and hold objective 950 such that a portion 951 of objective 950 is located on one side of stage 970 and a different portion 953 of objective 950 is located on an opposite side of stage 970. In some embodiments, objective 950 may be screwed into stage 970, for example. Note that this is one possible embodiment of many ways that stage 970 may support objective 950.

In addition to objective 950, metrology system 10 may include (and stage 970 and/or other components may support) various lenses, reflectors, and other optical components configured to receive, transmit, reflect, focus, and/or perform other operations on the radiation generated by a radiation source of metrology system 20, split by a beam splitter, transmitted or reflected by other optical elements, and/or used by other portions of metrology system 10. These various lenses, reflectors, and/or other optical components may comprise any type of lens, reflector, and/or other optical component configured to allow system 10 and system 900 to function as described. The various lenses, reflectors, optical elements, beam splitter, and/or other components may be positioned in any location and/or at any angle relative to each other that allows system 10 (including system 900) to function as described herein. This may include positioning at specific relative distances between elements, specific angles between elements, etc. The quantity of the various lenses, reflectors, and/or other optical components shown in FIG. 9 is not intended to be limiting. The principles described herein may be extended such that, in some embodiments system 900 comprises additional or fewer lenses, reflectors, and/or other optical components.

A positioner 902, 904, and/or 906 comprises at least one flexible support (e.g., 910, 912, 914, 916, 918, 920, 922 as described below) coupled to stage 970, a base (e.g., 930, 932, 934 as described below), a guide (e.g., 940, 942, 944 as described below), and/or other components. The at least one flexible support is configured to be relatively stiff in an axial direction of the positioner, and relatively flexible in other directions. The base is coupled to the at least one flexible support. The base is configured to be actuated to move in the axial direction, and in turn move stage 970. The guide is configured to couple the base to a frame of the metrology apparatus. The guide is configured to bend when the base is actuated.

For example, as shown in FIG. 9, positioning system 900 comprises first, second, and third positioners 902, 904, and 906 coupled to stage 970 and configured to move stage 970 in first 903 (e.g., X), second 905 (e.g., Y), and third 907 (e.g., Z) directions respectively. First, second, and third positioners 902, 904, and 906 are configured to move the stage in the first 903 (X), second 905 (Y), and third 907 (Z) directions independently, at different times and/or simultaneously, to precisely position objective 950 (the optical element for metrology). In some embodiments, coupling between the various components of each positioner, stage 970, and/or other components of positioning system 900 is provided by structural members, clips, clamps, screws, nuts, bolts, adhesive, orifices, and/or other mechanical devices.

First positioner 902 comprises a single flexible support 910. Single flexible support 910 is located at or near a center of a first side edge 971 of stage 970. Second positioner 904 comprises two flexible supports 912 and 914. The two flexible supports 912 and 914 are located at or near opposite corners 921 and 923 (hidden by other components in FIG. 9) of a second side edge 973 of stage 970. The two flexible supports 912 and 914 are configured to reduce or prevent undesired rotation of stage 970, and/or other motion, for example. Third positioner 906 comprises at least three flexible supports. In the example shown in FIG. 9, third positioner 906 comprises flexible supports 916, 918, 920, and 922. Third positioner 906 comprises four flexible supports 916, 918, 920, and 922 positioned at or near four corresponding corners 917, 919, 921, and 923 (hidden by other components in FIG. 9) of stage 970. The four flexible supports 916, 918, 920, and 922 are coupled to top surface 975 of stage 970 and configured to reduce or prevent undesired rotation and/or tilt (and/or other movement) of stage 970. The four flexible supports 916, 918, 920, and 922 of third positioner 906 are positioned around a porro prism 960 of the metrology apparatus.

Flexible supports 910, 912, 914, 916, 918, 920, and 922 are configured to be relatively stiff in an axial direction (e.g., a first 903 (X), second 905 (Y), or third 907 (Z) direction) of a corresponding positioner 902, 904, or 906, and relatively flexible in other directions. As shown in FIG. 9, flexible supports 910, 912, 914, 916, 918, 920, and 922 may have elongated bodies 991 in a corresponding axial direction. Elongated bodies 991 may have square, rectangular, circular, and/or other cross sectional shapes (elongated bodies 991 have generally square cross sectional shapes in the examples shown in FIG. 9). Elongated bodies 991 provide a stiff axial connection between stage 970 and the other components of a given positioner 902, 904, and/or 906. This stiff axial connection is configured to translate movement by other components of a given positioner to stage 970.

Flexible supports 910, 912, 914, 916, 918, 920, and 922 also include one or more reduced cross section portions 993 configured to provide relative flexibility in non-axial directions. In some embodiments, one or more spherical ball bearings may be provided to facilitate similar behavior. This relative flexibility is configured to absorb, reduce, or prevent undesired movement of stage 970. For example, undesired motion may include rotation in a direction Rx, Ry, and/or Rz. Here, Rz is constrained by 912 and 914. Rx and Ry are constrained by the four vertical struts described above. The relative flexibility is configured to allow the desired XYZ motion in the direction perpendicular to the driving direction. For example, positioner 904 provides Y motion, and supports 912 and 914 have flexibility in the X and Z directions to allow for that motion.

In some embodiments, flexible supports 910, 912, 914, 916, 918, 920, and 922 may be formed from metal, polymer, composite, and/or other materials. The relative stiffness in the axial direction and flexibility in non-axial directions may be provided at least in part by the material properties used to form flexible supports 910, 912, 914, 916, 918, 920, and 922.

Bases 930, 932, and 934 are coupled to corresponding flexible supports for the different positioners 902, 904, and 906. For example, base 930 is coupled to flexible support 910 in positioner 902. Base 932 is coupled to flexible supports 912 and 914 is positioner 904. Base 934 is coupled to flexible supports 916, 918, 920, and 922 in positioner 906. Bases 930, 932, and 934 are configured to be actuated to move in their corresponding axial directions (e.g., a first 903 (X), second 905 (Y), or third 907 (Z) direction), and in turn move stage 970. In some embodiments, a positioner 902, 904, 906 may include an actuator coupled to a base 930, 932, 934 configured to move the base in the axial direction, and in turn move stage 970 and the optical element (objective 950). In the example shown in FIG. 9, each base 930, 932, and 934 is illustrated as a rectangular surface configured to couple with such an actuator. Bases 930, 932, and 934 may have any shape and size that allows them to function as described herein.

In some embodiments, one or more actuators (not shown in FIG. 9) may be coupled to and configured to move one or more positioners 902, 904, and/or 906 of system 900. The actuators may be coupled to one or components of positioners 902, 904, and/or 906 (and/or system 10) by adhesive, clips, clamps, screws, a collar, and/or other mechanisms. The actuators may be configured to be controlled electronically. Individual actuators may be configured to convert an electrical signal into mechanical displacement. The mechanical displacement is configured to move a component of an positioner 902, 904, and/or 906 as described. As an example, one or more of the actuators may be piezoelectric. One or more processors (see PRO in FIG. 3) may be configured to control the actuators. One or more processors may be configured to individually control each of the one or more actuators.

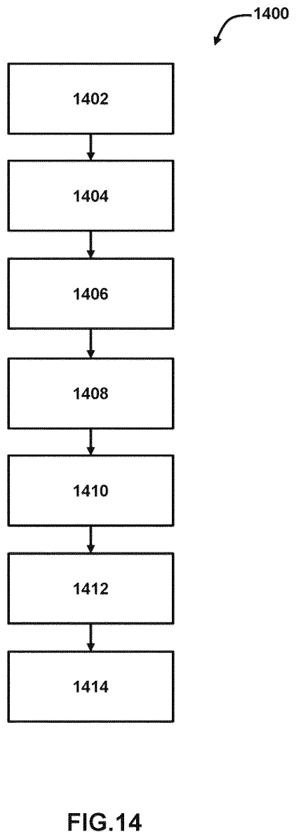

Movement may be configured to adjust locations of corresponding spots of radiation on one or more substrate targets, for example. In some embodiments, movement comprises translating or otherwise changing a distance between various components of system 900. In some embodiments, movement may be controlled electronically by a processor, such as processor PRO shown in FIG. 3 (and also in FIG. 14 discussed below). Processor PRO may be included in a computing system CS (FIG. 14) and may operate based on computer or machine readable instructions MRI (e.g., as described below related to FIG. 14). Electronic communication may occur by transmitting electronic signals between separate components, transmitting data between separate components of system 900 and/or system 10, transmitting data from a lithography apparatus (e.g., such as apparatus LA shown in FIG. 1) to system 10 and/or system 900, and/or other communication. The components of system 10 and/or system 900 may communicate via wires or wirelessly via a network, such as the Internet or the Internet in combination with various other networks, like local area networks, cellular networks, or personal area networks, internal organizational networks, and/or other networks.

Note that in system 900 and system 10, the motion of porro prism 960 is provided by separate, but similar components. This differs from the concept shown in FIG. 8 in which the prism was coupled to the objective's stage and a motion ratio was controlled by linkages.

Guides 940, 942, and 944 are configured to couple bases 930, 932, and 934, respectively, to a frame of a metrology apparatus (e.g., metrology system 10). The frame may be a sensor frame of metrology system 10, for example. The different guides couple the different bases to the same sensor frame. Guides 940, 942, and 944 are configured to bend when a corresponding base 930, 932, 934 is actuated. In some embodiments, a guide 940, 942, 944 comprises two parallel flexible plates positioned on opposite sides of the corresponding base. For example, guide 940 comprises parallel flexible plates 941 and 943. Plates 941 and 943 are coupled to opposite sides of base 930 in positioner 902. Plates 941 and 943 are configured to allow base 930 to move axially when actuated (as described above), without twisting, rotating, or becoming detached from the sensor frame. Guide 942 comprises parallel flexible plates 945 and 947. Plates 945 and 947 are coupled to opposite sides of base 932 in positioner 904. Plates 945 and 947 are configured to allow base 932 to move axially when actuated (as described above), without twisting, rotating, or becoming detached from the sensor frame. Guide 944 comprises parallel flexible plates 949 and 955. Plates 949 and 955 are coupled to opposite sides of base 934 in positioner 906. Plates 949 and 955 are configured to allow base 934 to move axially when actuated (as described above), without twisting, rotating, or becoming detached from the sensor frame.

In some embodiments, the parallel flexible plates may be formed from metal, polymer, composite, and/or other materials. The flexibility may be provided at least in part by the material properties used to form the parallel plates, a mechanical design of the parallel plates, a length, width, or thickness of the parallel plates, and/or other characteristics of the parallel plates. In some embodiments, a negative stiffness mechanism can be used to overcome the parasitic stiffness of the flexible supports. Parasitic stiffness is the stiffness in the motion direction that needs to be overcome by the actuator. A negative stiffness counteracts the parasitic stiffness and therefore reduces the force that needs to be applied by the actuators. This negative stiffness is not shown in FIG. 9, but may be added to the stage.

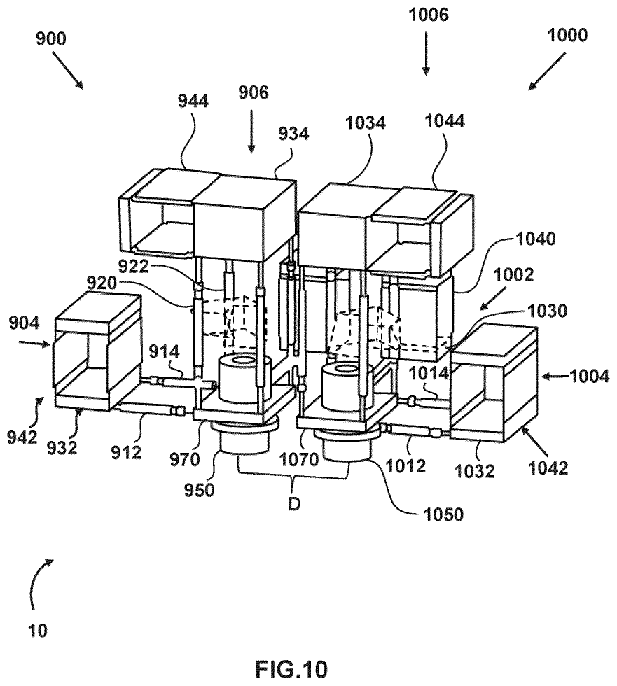

FIG. 10 illustrates a metrology apparatus such as system 10 described above comprising a second positioning system 1000 (in addition to positioning system 900). Second positioning system 1000 is configured to position a second objective 1050 to facilitate two simultaneous measurements on the same substrate (not shown in FIG. 10). Including two positioning systems to position two objectives in a metrology apparatus improves the utilization of the metrology apparatus in comparison to prior systems.

Pitch distance may be defined as a target to target distance within a substrate that varies based on customer design (e.g., small field: 22 mm, large field: 26 mm). Efficiency of the overall metrology system is improved with objectives placed at fewer pitch distances. In some embodiments, second positioning system 1000 is configured such that a distance D from objective 1050 to objective 950 in the metrology apparatus is equal to or less than a target distance. For example, distance D may be less than or equal to about 60 mm. In some embodiments, distance D may be less than or equal to about 48 mm. In some embodiments, distance D may be less than or equal to about 45 mm. In some embodiments, distance D may be between 44 mm and 52 mm. Note that in some embodiments, the system components described above may be oriented in the y-direction of the system (as described above they are oriented in the x-direction). In such an orientation, a maximum field size may be about 33 mm and a minimum field size may be about 28 mm, but this is one example only, and larger or smaller field sizes may be configured as well.

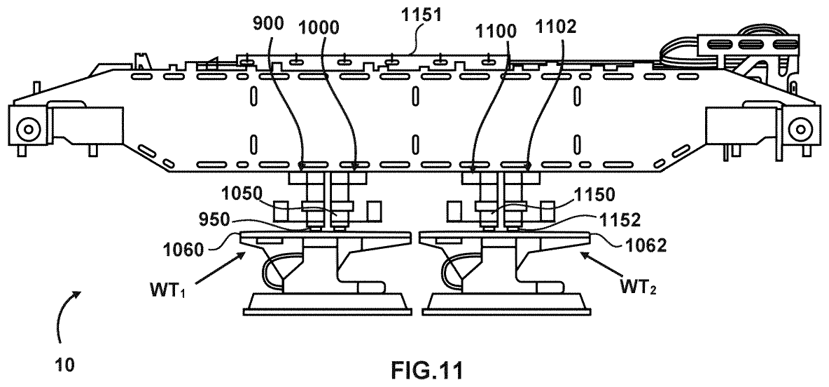

As shown in FIG. 10, components of second positioning system 1000 correspond to the components of positioning system 900. By way of several examples, FIG. 10 illustrates positioners 1002, 1004, and 1006; flexible supports 1012 and 1014; a stage 1070; an objective 1050; bases 1030, 1032, and 1034; and guides 1040, 1042, 1044 (note that not every corresponding component is shown in FIG. 10 due to the size and perspective of FIG. 10 obscuring some components from clear view). FIG. 11 illustrates a metrology apparatus such as system 10 described above comprising

third and fourth positioning systems 1100 and 1102, in addition to second positioning system 1000 and positioning system 900. Third and fourth positioning systems 1100 and 1102 are configured to position third and fourth objectives 1150 and 1152, respectively, to facilitate simultaneous measurements different substrates 1060 and 1062 (supported by substrate tables WT₁ and WT₂), for example. FIG. 11 also illustrates a sensor frame 1151 (in cross section). As described above, guides 940, 942, and 944 (FIG. 9), and corresponding guides of positioning systems 1000, 1100, and 1102 are configured to couple bases 930, 932, and 934 (FIG. 9), respectively, and corresponding bases of positioning systems 1000, 1100, and 1102, to frame 1151.

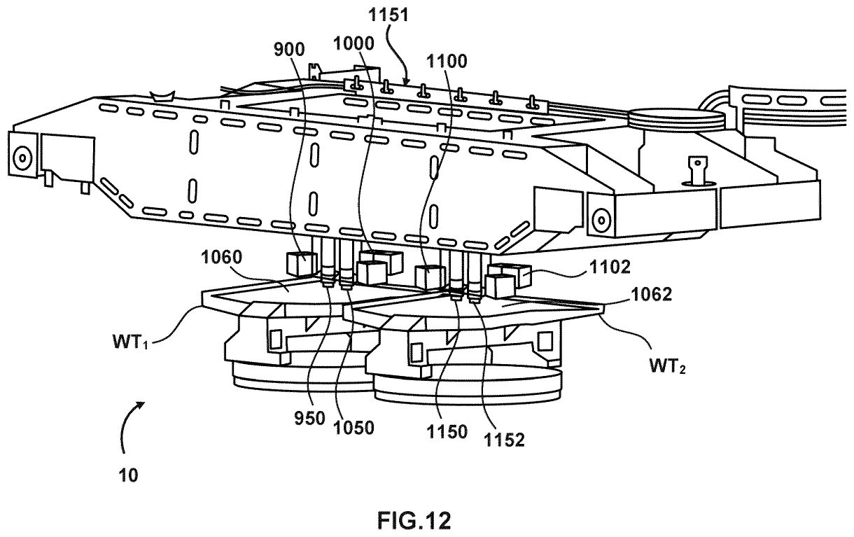

FIG. 12 provides a perspective view of the metrology apparatus shown in FIG. 11. FIG. 11 illustrates third and fourth positioning systems 1100 and 1102, in addition to second positioning system 1000 and positioning system 900. First, second, third, and fourth objectives 950, 1050, 1150 and 1152, respectively, are also illustrated, along with substrates 1060 and 1062, and substrate tables WT₁ and WT₂. Note that the light from the four objectives comes from and goes to a central sensor, which is located (but not visualized in this figure) in the metrology frame.

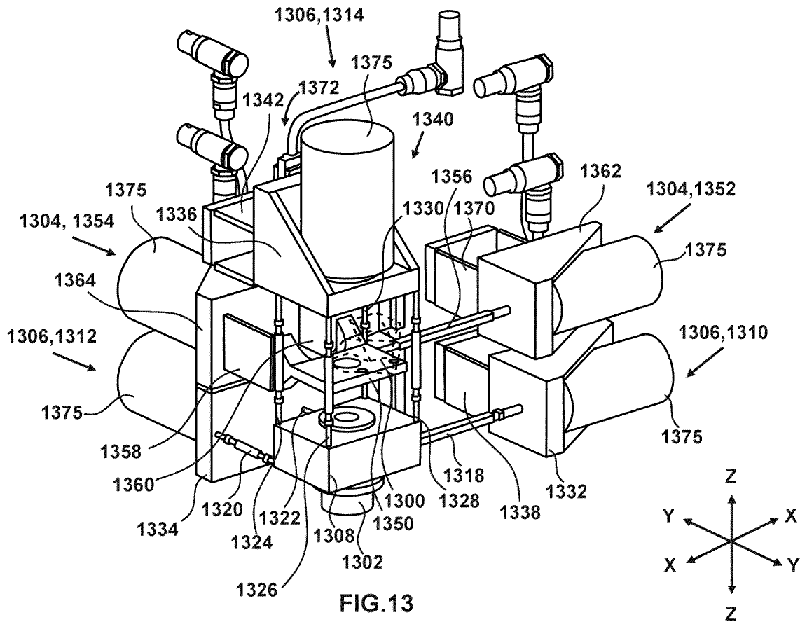

FIG. 13 illustrates a (portion of a) metrology apparatus having a prism component 1300 (e.g., a double porro prism as described above) and an objective 1302, with corresponding prism and objective positioning systems 1304 and 1306. Objective positioning system 1306 shown in FIG. 13 may have some and/or all of the same components (or similar components) as system 900 shown in FIG. 9, for example. In FIG. 13, objective positioning system 1306 comprises an objective stage 1308 configured to support objective 1302; and first, second, and third objective positioners 1310, 1312, 1314 coupled to the objective stage and configured to move the objective stage in X, Y, and Z directions respectively. An objective positioner 1310, 1312, and/or 1324 comprises at least one flexible objective support 1318, 1320, 1322, 1324, 1326, 1328, and/or 1330 coupled to stage 1308. The at least one flexible objective support 1318-1330 is configured to be relatively stiff in an axial direction of the objective positioner, and relatively flexible in other directions. An objective positioner 1310-1314 comprises a corresponding objective base 1332, 1334, and/or 1336 coupled to the at least one flexible objective support 1318-1330. An objective base 1332-1336 is configured to be actuated to move in the axial direction (for that positioner), and in turn move objective stage 1308 and objective 1302 to direct the radiation toward a target on a substrate. An objective positioner 1310-1314 comprises a corresponding objective guide 1338, 1340 (not visible in FIG. 13), 1342 configured to couple the objective base 1332-1336 to a frame of the metrology apparatus (not shown in FIG. 13). An objective guide 1338-1342 is configured to bend when the corresponding objective base 1332-1336 is actuated, but remain coupled to the frame.

Prism positioning system 1304 comprises a prism stage 1350 configured to support prism component 1300. First and second prism positioners 1352 and 1354 are coupled to prism stage 1350 and are configured to move prism stage 1350 in X and Y directions respectively. A prism positioner 1352 and/or 1354 comprises at least one flexible prism support 1356, 1358, 1360 coupled to prism stage 1350. The at least one flexible prism support 1356-1360 is configured to be relatively stiff in an axial direction of the prism positioner 1310 or 1312, and relatively flexible in other directions. A prism positioner 1352 and/or 1354 comprises a prism base 1362, 1364 coupled to the at least one flexible prism support 1356-1360. A prism base 1362 and/or 1364 is configured to be actuated to move in the axial direction for that positioner, and in turn move prism stage 1350 and prism component 1300 to direct radiation toward the target on the substrate. A prism positioner 1352 and/or 1354 comprises a prism guide 1370 and/or 1372 (not visible in FIG. 13) configured to couple a prism base 1362 and/or 1364 to the frame of the metrology apparatus. A prism guide 1370 and/or 1372 is configured to bend when a corresponding prism base 1362, 1364 is actuated, but remain coupled to the frame.

In some embodiments, the first, second, and third objective positioners 1310-1314 are configured to move objective stage 1308 in the X, Y, and Z directions; and the first and second prism positioners 1352-1354 are configured to move prism stage 1350 in the X and Y directions, independently, at different times, and/or simultaneously, to precisely position objective 1302 and/or prism component 1300 for metrology. In some embodiments, the first (X direction) prism positioner 1352 comprises a single flexible support 1356, and the second (Y direction) prism positioner 1354 comprises two flexible supports 1358 and 1360. The two flexible supports 1358 and 1360 of second prism positioner 1354 may be located at or near opposite corners of a first side edge of prism stage 1350, for example, and the single flexible support 1356 of first prism positioner 1352 may be located at or near a center of a second side edge of prism stage 1350 (e.g., according to the example embodiment shown in FIG. 13). In some embodiments, the two flexible supports 1358 and 1360 of second prism positioner 1354 comprise parallel rectangular plates, and the single flexible support 1356 of first prism positioner 1352 comprises an elongated body having a square or rectangular cross section, though these are just a few examples of many possible configurations of supports 1356, 1358, and/or 1360.

In some embodiments, actuation of one or more of the positioners shown in FIG. 13 (or any other figure) may be facilitated by voice coil and/or other actuators (e.g., 1375 shown in FIG. 13), optical encoders (e.g., 1377 shown in FIG. 13), and/or other components.

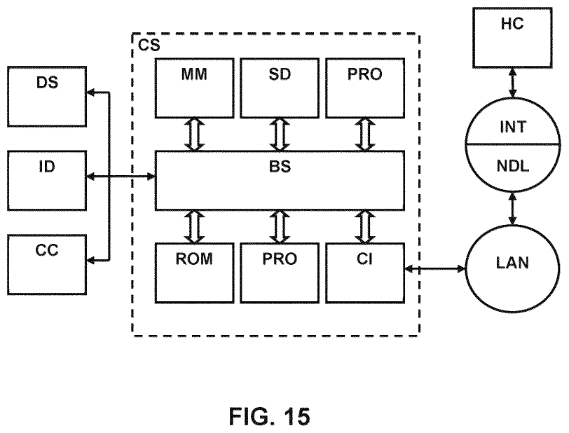

FIG. 14 illustrates a metrology method 1400. Some or all of method 1400 may be performed with a metrology apparatus such as metrology (inspection) system 10 shown in FIG. 3 and described above, the positioning system described above, a computer system (e.g., as illustrated in FIG. 15 and described below, and/or other systems. In some embodiments, method 1400 is performed as part of an overlay and/or alignment sensing operation in a semiconductor device manufacturing process, for example. In some embodiments, method 1400 comprises generating (operation 1402) radiation, supporting (operation 1404) an optical component such as an objective with a stage of the metrology apparatus, moving (operation 1406) the stage with first, second, and third positioners of a first positioning system of the metrology apparatus, coupling (1408) at least one flexible support to the stage, coupling (operation 1410) a base coupled to the at least one flexible support, coupling (operation 1412) the base to a frame of the metrology apparatus; and receiving (operation 1414), with a detector, diffracted and reflected radiation from a target and generating a detection signal, and/or other operations.

The operations of method 1400 are intended to be illustrative. In some embodiments, method 1400 may be accomplished with one or more additional operations not described, and/or without one or more of the operations discussed. For example, in some embodiments, method 1400 may include an additional operation comprising determining an adjustment for a semiconductor device manufacturing process. As another example, method 1400 may include corresponding operations for positioning a double porro prism in conjunction with positioning an objective, with the apparatus shown in FIG. 13. Note that the order in which the operations of method 1400 are illustrated in FIG. 14 and described herein is not intended to be limiting.

In some embodiments, one or more portions of method 1400 may be implemented in and/or controlled by one or more processing devices (e.g., a digital processor, an analog processor, a digital circuit designed to process information, an analog circuit designed to process information, a state machine, and/or other mechanisms for electronically processing information). The one or more processing devices may include one or more devices executing some or all of the operations of method 1400 in response to instructions stored electronically on an electronic storage medium. The one or more processing devices may include one or more devices configured through hardware, firmware, and/or software to be specifically designed for execution of one or more of the operations of method 1400 (e.g., see discussion related to FIG. 15 below).

At operation 1402, radiation is generated with a radiation source of a metrology apparatus, and directed toward a prism component and an objective along an optical path. In some embodiments, operation 1402 includes illuminating (and/or otherwise irradiating) one or more targets (e.g., target 30 shown in FIG. 3) in a patterned substrate with radiation. The radiation comprises light and/or other radiation separated into illumination spots as described above. The radiation may be generated by a radiation source (e.g., source 2 shown in FIG. 3). In some embodiments, the radiation may be directed by the radiation source onto multiple targes, a single target, sub-portions (e.g., something less than the whole) of a target, and/or onto a substrate in other ways. In some embodiments, the radiation may be directed by the radiation source onto the target in a time varying manner. For example, the radiation may be rastered over a target (e.g., by moving the target under the radiation) such that different portions of the target are irradiated at different times. As another example, characteristics of the radiation (e.g., wavelength, intensity, etc.) may be varied. This may create time varying data envelopes, or windows, for analysis. The data envelopes may facilitate analysis of individual sub-portions of a target, comparison of one portion of a target to another and/or to other targets (e.g., in other layers), and/or other analysis.

In some embodiments, the prism component is a porro prism such as porro prism 960 described above, and/or other prism components. In some embodiments, the objective is similar to and/or the same as objective 950 described above, and/or other objectives. In some embodiments, operation 1402 comprises providing the radiation source (e.g., source 2 shown in FIG. 3).

At operation 1404, the objective is supported with a stage of the metrology apparatus. The stage may be similar to and/or the same as stage 970 described above, and/or other stages.

At operation 1406, the stage is moved with first, second, and third positioners of a first positioning system of the metrology apparatus. The first, second, and third positioners are coupled to the stage, and configured to move the stage in X, Y, and Z directions respectively. The first, second, and third positioners are configured to move the stage in the X, Y, and Z directions independently, at different times and/or simultaneously, to precisely position an objective for metrology. The positioning system may be similar to and/or the same as positioning system 900 described above, and/or other positioning systems. The first, second, and third positioners may be similar to and/or the same as positioners 902, 904, and 906 described above, and/or other positioners.

In some embodiments, operation 1406 comprises positioning, with a second positioning system, a second objective to facilitate two simultaneous measurements on the same substrate (see discussion related to FIG. 10 above). In some embodiments, the second positioning system is configured such that a distance from one objective to another in the metrology apparatus is about 48 mm. In some embodiments, operation 1406 comprises positioning, with third and fourth positioning systems, third and fourth objectives, respectively, to facilitate two additional simultaneous measurements on a second substrate by the metrology apparatus (see discussion related to FIG. 11 above).

At operation 1408, at least one flexible support is coupled to the stage. The at least one flexible support is configured to be relatively stiff in an axial direction of the positioner, and relatively flexible in other directions. The at least one flexible support may be similar to and/or the same as any of flexible supports 910-922 described above, and/or other flexible supports.

In some embodiments, the first positioner comprises a single flexible support, the second positioner comprises two flexible supports, and the third positioner comprises four flexible supports. In some embodiments, the single flexible support of the first positioner is located at or near a center of a first side edge of the stage. The two flexible supports of the second positioner may be located at or near opposite corners of a second side edge of the stage. The two flexible supports are configured to reduce or prevent undesired rotation of the stage. The four flexible supports of the third positioner may be coupled to a top surface of the stage and configured to reduce or prevent undesired rotation and/or tilt of the stage, for example. The four flexible supports of the third positioner may be positioned around the prism component (e.g., the porro prism) of the metrology apparatus.

At operation 1410, a base is coupled to the at least one flexible support. The base is configured to be actuated to move in the axial direction, and in turn move the stage and the objective to direct the radiation toward a target on a substrate. The base may be similar to and/or the same as any of bases 930-934 described above, and/or other bases.

At operation 1412, the base is coupled to a frame of the metrology apparatus with a guide. The guide is configured to bend when the base is actuated, but remain coupled to the frame. In some embodiments, the guide comprises two parallel flexible plates positioned on opposite sides of the base. The guide may be similar to and/or the same as any of guides 940-944 described above, and/or other guides.

At operation 1414, diffracted and reflected radiation from a target are received with a detector, and a detection signal is generated. In some embodiments, operation 1414 comprises detecting reflected radiation from one or more diffraction grating targets. Detecting reflected radiation comprises detecting one or more phase and/or amplitude (intensity) shifts in reflected radiation from one or more geometric features of the target(s). The one or more phase and/or amplitude shifts correspond to one or more dimensions of a target. For example, the phase and/or amplitude of reflected radiation from one side of a target is different relative to the phase and/or amplitude of reflected radiation from another side of the target.

Detecting the one or more phase and/or amplitude (intensity) shifts in the reflected radiation from the target comprises measuring local phase shifts (e.g., local phase deltas) and/or amplitude variations that correspond to different portions of a target. For example, the reflected radiation from a specific area of a target may comprise a sinusoidal waveform having a certain phase and/or amplitude. The reflected radiation from a different area of the target (or a target in a different layer) may also comprise a sinusoidal waveform, but one with a different phase and/or amplitude. Detected reflected radiation also comprises measuring a phase and/or amplitude difference in reflected radiation of different diffraction orders. Detecting the one or more local phase and/or amplitude shifts may be performed using Hilbert transformations, for example, and/or other techniques. Interferometry techniques and/or other operations may be used to measure phase and/or amplitude differences in reflected radiation of different diffraction orders.

In some embodiments, generating the detection signal comprises generating a metrology signal based on the detected reflected radiation from diffraction grating target(s), as described above. The metrology signal is generated by a sensor (such as detector 4 in FIG. 3, a camera, and/or other sensors) based on radiation received by the sensor. The metrology signal comprises measurement information pertaining to the target(s). For example, the metrology signal may be an overlay and/or alignment signal comprising overlay and/or alignment measurement information, and/or other metrology signals. The measurement information (e.g., an overlay value, an alignment value, and/or other information) may be determined using principles of interferometry and/or other principles.

The metrology signal comprises an electronic signal that represents and/or otherwise corresponds to the radiation reflected from the target(s). The metrology signal may indicate a metrology value associated with a diffraction grating target, for example, and/or other information. Generating the metrology signal comprises sensing the reflected radiation and converting the sensed reflected radiation into the electronic signal. In some embodiments, generating the metrology signal comprises sensing different portions of the reflected radiation from different areas and/or different geometries of the target, and/or multiple targets, and combining the different portions of the reflected radiation to form the metrology signal. This may include generating and/or analyzing one or more images of a target, using the radiation described herein. This sensing and converting may be performed by components similar to and/or the same as detector 4 and/or processors PRO shown in FIG. 3, and/or other components.

Operation 1414 may include determining overlay and/or alignment. Overlay and/or alignment may be determined based on reflected diffracted radiation from the diffraction grating target, for example, and/or based on other information. In some embodiments, operation 1414 is performed by a detector the same as or similar to detector 4 and processor PRO shown in FIG. 3 and described above, and/or other detectors.

In some embodiments, method 1400 comprises one or more additional operations such as determining an adjustment for a semiconductor device manufacturing process. In some embodiments, method 1400 includes determining one or more semiconductor device manufacturing process parameters. The one or more semiconductor device manufacturing process parameters may be determined based on one or more detected phase and/or amplitude variations, an overlay and/or alignment value indicated by the metrology signal, and/or other similar systems, and/or other information. The one or more parameters may include a parameter of the radiation (the radiation used for metrology), an overlay value, an alignment value, a metrology inspection location on a layer of a semiconductor device structure, a radiation beam trajectory across a target, and/or other parameters. In some embodiments, process parameters can be interpreted broadly to include a (metrology and/or wafer) stage position, a mask design, a metrology target design, a semiconductor device design, an intensity of the radiation (used for exposing resist, etc.), an incident angle of the radiation (used for exposing resist, etc.), a wavelength of the radiation (used for exposing resist, etc.), a pupil size and/or shape, a resist material, and/or other parameters.

In some embodiments, method 1400 includes determining a process adjustment based on the one or more determined semiconductor device manufacturing process parameters, adjusting a semiconductor device manufacturing apparatus based on the determined adjustment, and/or other operations. For example, if a determined metrology measurement is not within process tolerances, the out of tolerance measurement may be caused by one or more manufacturing processes whose process parameters have drifted and/or otherwise changed so that the process is no longer producing acceptable devices (e.g., measurements may breach a threshold for acceptability). One or more new or adjusted process parameters may be determined based on the measurement determination. The new or adjusted process parameters may be configured to cause a manufacturing process to again produce acceptable devices.

For example, a new or adjusted process parameter may cause a previously unacceptable measurement value to be adjusted back into an acceptable range. The new or adjusted process parameters may be compared to existing parameters for a given process. If there is a difference, that difference may be used to determine an adjustment for an apparatus that is used to produce the devices (e.g., parameter “x” should be increased/decreased/changed so that it matches the new or adjusted version of parameter “x” determined as part of method 1400), for example. In some embodiments, method 1300 may include electronically adjusting an apparatus (e.g., based on the determined process parameters). Electronically adjusting an apparatus may include sending an electronic signal, and/or other communications to the apparatus, for example, which causes a change in the apparatus. The electronic adjustment may include changing a setting on the apparatus, for example, and/or other adjustments.

FIG. 15 is a diagram of an example computer system CS that may be used for one or more of the operations described herein. Computer system CS includes a bus BS or other communication mechanism for communicating information, and a processor PRO (or multiple processors similar to and/or the same as processor PRO shown in FIG. 3) coupled with bus BS for processing information. Computer system CS also includes a main memory MM, such as a random access memory (RAM) or other dynamic storage device, coupled to bus BS for storing information and instructions to be executed by processor PRO. Main memory MM also may be used for storing temporary variables or other intermediate information during execution of instructions by processor PRO. Computer system CS further includes a read only memory (ROM) ROM or other static storage device coupled to bus BS for storing static information and instructions for processor PRO. A storage device SD, such as a magnetic disk or optical disk, is provided and coupled to bus BS for storing information and instructions.

Computer system CS may be coupled via bus BS to a display DS, such as a flat panel or touch panel display or a cathode ray tube (CRT) for displaying information to a computer user. An input device ID, including alphanumeric and other keys, is coupled to bus BS for communicating information and command selections to processor PRO. Another type of user input device is cursor control CC, such as a mouse, a trackball, or cursor direction keys for communicating direction information and command selections to processor PRO and for controlling cursor movement on display DS. This input device typically has two degrees of freedom in two axes, a first axis (e.g., x) and a second axis (e.g., y), that allows the device to specify positions in a plane. A touch panel (screen) display may also be used as an input device.

In some embodiments, all or some of one or more operations described herein (e.g., controlling actuators to move a stage, controlling a metrology apparatus, analyzing sensor data, etc.) may be performed by computer system CS in response to processor PRO executing one or more sequences of one or more instructions contained in main memory MM. Such instructions may be read into main memory MM from another computer-readable medium, such as storage device SD. Execution of the sequences of instructions included in main memory MM causes processor PRO to perform the process steps (operations) described herein. One or more processors in a multi-processing arrangement may also be employed to execute the sequences of instructions contained in main memory MM. In some embodiments, hard-wired circuitry may be used in place of or in combination with software instructions. Thus, the description herein is not limited to any specific combination of hardware circuitry and software.

The term “computer-readable medium” or “machine-readable medium” as used herein refers to any medium that participates in providing instructions to processor PRO for execution. Such a medium may take many forms, including but not limited to, non-volatile media, volatile media, and transmission media. Non-volatile media include, for example, optical or magnetic disks, such as storage device SD. Volatile media include dynamic memory, such as main memory MM. Transmission media include coaxial cables, copper wire and fiber optics, including the wires that comprise bus BS. Transmission media can also take the form of acoustic or light waves, such as those generated during radio frequency (RF) and infrared (IR) data communications. Computer-readable media can be non-transitory, for example, a floppy disk, a flexible disk, hard disk, magnetic tape, any other magnetic medium, a CD-ROM, DVD, any other optical medium, punch cards, paper tape, any other physical medium with patterns of holes, a RAM, a PROM, and EPROM, a FLASH-EPROM, any other memory chip or cartridge. Non-transitory computer readable media can have instructions recorded thereon. The instructions, when executed by a computer, can implement any of the operations described herein. Transitory computer-readable media can include a carrier wave or other propagating electromagnetic signal, for example.

Various forms of computer readable media may be involved in carrying one or more sequences of one or more instructions to processor PRO for execution. For example, the instructions may initially be borne on a magnetic disk of a remote computer. The remote computer can load the instructions into its dynamic memory and send the instructions over a telephone line using a modem. A modem local to computer system CS can receive the data on the telephone line and use an infrared transmitter to convert the data to an infrared signal. An infrared detector coupled to bus BS can receive the data carried in the infrared signal and place the data on bus BS. Bus BS carries the data to main memory MM, from which processor PRO retrieves and executes the instructions. The instructions received by main memory MM may optionally be stored on storage device SD either before or after execution by processor PRO.

Computer system CS may also include a communication interface CI coupled to bus BS. Communication interface CI provides a two-way data communication coupling to a network link NDL that is connected to a local network LAN. For example, communication interface CI may be an integrated services digital network (ISDN) card or a modem to provide a data communication connection to a corresponding type of telephone line. As another example, communication interface CI may be a local area network (LAN) card to provide a data communication connection to a compatible LAN. Wireless links may also be implemented. In any such implementation, communication interface CI sends and receives electrical, electromagnetic or optical signals that carry digital data streams representing various types of information.

Network link NDL typically provides data communication through one or more networks to other data devices. For example, network link NDL may provide a connection through local network LAN to a host computer HC. This can include data communication services provided through the worldwide packet data communication network, now commonly referred to as the “Internet” INT. Local network LAN (Internet) may use electrical, electromagnetic or optical signals that carry digital data streams. The signals through the various networks and the signals on network data link NDL and through communication interface CI, which carry the digital data to and from computer system CS, are exemplary forms of carrier waves transporting the information.

Computer system CS can send messages and receive data, including program code, through the network(s), network data link NDL, and communication interface CI. In the Internet example, host computer HC might transmit a requested code for an application program through Internet INT, network data link NDL, local network LAN, and communication interface CI. One such downloaded application may provide all or part of a method described herein, for example. The received code may be executed by processor PRO as it is received, and/or stored in storage device SD, or other non-volatile storage for later execution. In this manner, computer system CS may obtain application code in the form of a carrier wave.

Various embodiments of the present systems and methods are disclosed in the subsequent list of numbered clauses. In the following, further features, characteristics, and exemplary technical solutions of the present disclosure will be described in terms of clauses that may be optionally claimed in any combination:
1. A positioning system for an optical element of a metrology apparatus, the positioning system comprising: a stage; and a positioner comprising: at least one flexible support coupled to the stage, the at least one flexible support configured to be relatively stiff in an axial direction of the positioner, and relatively flexible in other directions; a base coupled to the at least one flexible support, the base configured to be actuated to move in the axial direction, and in turn move the stage; and a guide configured to couple the base to a frame of the metrology apparatus, the guide configured to bend when the base is actuated.
2. The system of clause 1, wherein the positioning system comprises first, second, and third positioners coupled to the stage and configured to move the stage in X, Y, and Z directions respectively.
3. The system of any of the previous clauses, wherein the first, second, and third positioners are configured to move the stage in the X, Y, and Z directions independently, at different times and/or simultaneously, to precisely position the optical element for metrology, the optical element supported by the stage.
4. The system of any of the previous clauses, wherein the first positioner comprises a single flexible support, the second positioner comprises two flexible supports, and the third positioner comprises at least three flexible supports.
5. The system of any of the previous clauses, wherein the third positioner comprises four flexible supports positioned at or near four corresponding corners of the stage.
6. The system of any of the previous clauses, wherein the single flexible support of the first positioner is located at or near a center of a first side edge of the stage.
7. The system of any of the previous clauses, wherein the two flexible supports of the second positioner are located at or near opposite corners of a second side edge of the stage, the two flexible supports configured to reduce or prevent undesired rotation of the stage.
8. The system of any of the previous clauses, wherein the four flexible supports of the third positioner are coupled to a top surface of the stage and configured to reduce or prevent undesired rotation and/or tilt of the stage.
9. The system of any of the previous clauses, wherein the four flexible supports of the third positioner are positioned around a porro prism of the metrology apparatus.
10. The system of any of the previous clauses, wherein the optical element is an objective.
11. The system of any of the previous clauses, wherein the guide comprises two parallel flexible plates positioned on opposite sides of the base.
12. The system of any of the previous clauses, wherein the frame is a sensor frame of the metrology apparatus.
13. The system of any of the previous clauses, wherein the positioner is configured to move the optical element for overlay measurements.
14. The system of any of the previous clauses, wherein the overlay measurements are for a semiconductor wafer, and are made as part of a semiconductor manufacturing process.
15. The system of any of the previous clauses, the positioner further comprising an actuator coupled to the base configured to move the base in the axial direction, and in turn move the stage and the optical element.
16. A metrology apparatus comprising: a radiation source, the radiation source configured to generate radiation directed toward a prism component and an objective along an optical path; a positioning system for the objective, the positioning system comprising: a stage configured to support the objective; and first, second, and third positioners coupled to the stage and configured to move the stage in X, Y, and Z directions respectively, a positioner comprising: at least one flexible support coupled to the stage, the at least one flexible support configured to be relatively stiff in an axial direction of the positioner, and relatively flexible in other directions; a base coupled to the at least one flexible support, the base configured to be actuated to move in the axial direction, and in turn move the stage and the objective to direct the radiation toward a target on a substrate; and a guide configured to couple the base to a frame of the metrology apparatus, the guide configured to bend when the base is actuated, but remain coupled to the frame; and a detector, the detector configured to receive diffracted and reflected radiation from the target and generate a detection signal.
17. The metrology apparatus of clause 16, further comprising a second positioning system, the second positioning system configured to position a second objective to facilitate two simultaneous measurements on the same substrate.
18. The metrology apparatus of any of the previous clauses, wherein the second positioning system is configured such that a distance from one objective to another in the metrology apparatus is about 48 mm.
19. The metrology apparatus of any of the previous clauses, further comprising third and fourth positioning systems configured to position third and fourth objectives, respectively, to facilitate two additional simultaneous measurements on a second substrate by the metrology apparatus.
20. The metrology apparatus of any of any of the previous clauses, wherein the first, second, and third positioners are configured to move the stage in the X, Y, and Z directions independently, at different times and/or simultaneously, to precisely position an objective for metrology.
21. The metrology apparatus of any of the previous clauses, wherein the first positioner comprises a single flexible support, the second positioner comprises two flexible supports, and the third positioner comprises four flexible supports.
22. The metrology apparatus of any of the previous clauses, wherein the single flexible support of the first positioner is located at or near a center of a first side edge of the stage; the two flexible supports of the second positioner are located at or near opposite corners of a second side edge of the stage, the two flexible supports configured to reduce or prevent undesired rotation of the stage; and the four flexible supports of the third positioner are coupled to a top surface of the stage and configured to reduce or prevent undesired rotation and/or tilt of the stage.
23. The metrology apparatus of any of the previous clauses, wherein the four flexible supports of the third positioner are positioned around the prism component of the metrology apparatus.
24. The metrology apparatus of any of the previous clauses, wherein the guide comprises two parallel flexible plates positioned on opposite sides of the base.
25. The metrology apparatus of any of the previous clauses, wherein the metrology apparatus is configured for overlay measurements for a semiconductor wafer, and are made as part of a semiconductor manufacturing process.
26. A method for positioning an optical element of a metrology apparatus, the method comprising: supporting the optical element with a stage; coupling at least one flexible support of a positioner to the stage, the at least one flexible support configured to be relatively stiff in an axial direction of the positioner, and relatively flexible in other directions; coupling a base of the positioner to the at least one flexible support, the base configured to be actuated to move in the axial direction, and in turn move the stage; coupling the base to a frame of the metrology apparatus with a guide of the positioner, the guide configured to bend when the base is actuated; and actuating the base to move in the axial direction to move the stage and position the optical element.
27. The method of clause 26, wherein the positioning system comprises first, second, and third positioners coupled to the stage and configured to move the stage in X, Y, and Z directions respectively.
28. The method of any of the previous clauses, wherein the first, second, and third positioners are configured to move the stage in the X, Y, and Z directions independently, at different times and/or simultaneously, to precisely position the optical element for metrology, the optical element supported by the stage.
29. The method of any of the previous clauses, wherein the first positioner comprises a single flexible support, the second positioner comprises two flexible supports, and the third positioner comprises at least three flexible supports.
30. The method of any of any of the previous clauses, wherein the third positioner comprises four flexible supports positioned at or near four corresponding corners of the stage.
31. The method of any of the previous clauses, wherein the single flexible support of the first positioner is located at or near a center of a first side edge of the stage.
32. The method of any of the previous clauses, wherein the two flexible supports of the second positioner are located at or near opposite corners of a second side edge of the stage, the two flexible supports configured to reduce or prevent undesired rotation of the stage.
33. The method of any of the previous clauses, wherein the four flexible supports of the third positioner are coupled to a top surface of the stage and configured to reduce or prevent undesired rotation and/or tilt of the stage.
34. The method of any of the previous clauses, wherein the four flexible supports of the third positioner are positioned around a porro prism of the metrology apparatus.
35. The method of any of any of the previous clauses, wherein the optical element is an objective.
36. The method of any of any of the previous clauses, wherein the guide comprises two parallel flexible plates positioned on opposite sides of the base.
37. The method of any of any of the previous clauses, wherein the frame is a sensor frame of the metrology apparatus.
38. The method of any of any of the previous clauses, further comprising moving the optical element with the positioner for overlay measurements.
39. The method of any of the previous clauses, wherein the overlay measurements are for a semiconductor wafer, and are made as part of a semiconductor manufacturing process.
40. The method of any of the previous clauses, the positioner further comprising an actuator coupled to the base configured to move the base in the axial direction, and in turn move the stage and the optical element.
41. A method performed with a metrology apparatus, the method comprising: generating, with a radiation source of the metrology apparatus, radiation directed toward a prism component and an objective along an optical path; supporting the objective with a stage of the metrology apparatus; moving the stage with first, second, and third positioners of a first positioning system of the metrology apparatus, the first, second, and third positioners coupled to the stage, and configured to move the stage in X, Y, and Z directions respectively; coupling at least one flexible support to the stage, the at least one flexible support configured to be relatively stiff in an axial direction of the positioner, and relatively flexible in other directions; coupling a base coupled to the at least one flexible support, the base configured to be actuated to move in the axial direction, and in turn move the stage and the objective to direct the radiation toward a target on a substrate; coupling, with a guide, the base to a frame of the metrology apparatus, the guide configured to bend when the base is actuated, but remain coupled to the frame; and receiving, with a detector, diffracted and reflected radiation from the target and generate a detection signal.
42. The method of clause 41, further comprising positioning, with a second positioning system, a second objective to facilitate two simultaneous measurements on the same substrate.
43. The method of any of the previous clauses, wherein the second positioning system is configured such that a distance from one objective to another in the metrology apparatus is about 48 mm.
44. The method of any of the previous clauses, further comprising positioning, with third and fourth positioning systems, third and fourth objectives, respectively, to facilitate two additional simultaneous measurements on a second substrate by the metrology apparatus.
45. The method of any of the previous clauses, wherein the first, second, and third positioners are configured to move the stage in the X, Y, and Z directions independently, at different times and/or simultaneously, to precisely position an objective for metrology.
46. The method of any of the previous clauses, wherein the first positioner comprises a single flexible support, the second positioner comprises two flexible supports, and the third positioner comprises four flexible supports.
47. The method of any of the previous clauses, wherein the single flexible support of the first positioner is located at or near a center of a first side edge of the stage; the two flexible supports of the second positioner are located at or near opposite corners of a second side edge of the stage, the two flexible supports configured to reduce or prevent undesired rotation of the stage; and the four flexible supports of the third positioner are coupled to a top surface of the stage and configured to reduce or prevent undesired rotation and/or tilt of the stage.
48. The method of any of the previous clauses, wherein the four flexible supports of the third positioner are positioned around the prism component of the metrology apparatus.
49. The method of any of the previous clauses, wherein the guide comprises two parallel flexible plates positioned on opposite sides of the base.
50. The method of any of the previous clauses, wherein the metrology apparatus is configured for overlay measurements for a semiconductor wafer, and are made as part of a semiconductor manufacturing process.
51. A metrology apparatus having a prism component and an objective, the metrology apparatus comprising: an objective positioning system, the objective positioning system comprising: an objective stage configured to support the objective; and first, second, and third objective positioners coupled to the objective stage and configured to move the objective stage in X, Y, and Z directions respectively, an objective positioner comprising: at least one flexible objective support coupled to the stage, the at least one flexible objective support configured to be relatively stiff in an axial direction of the objective positioner, and relatively flexible in other directions; an objective base coupled to the at least one flexible objective support, the objective base configured to be actuated to move in the axial direction, and in turn move the objective stage and the objective to direct the radiation toward a target on a substrate; and an objective guide configured to couple the objective base to a frame of the metrology apparatus, the objective guide configured to bend when the objective base is actuated, but remain coupled to the frame; and a prism positioning system, the prism positioning system comprising: a prism stage configured to support the prism component; and first and second prism positioners coupled to the prism stage and configured to move the prism stage in X and Y directions respectively, a prism positioner comprising: at least one flexible prism support coupled to the prism stage, the at least one flexible prism support configured to be relatively stiff in an axial direction of the prism positioner, and relatively flexible in other directions; a prism base coupled to the at least one flexible prism support, the prism base configured to be actuated to move in the axial direction, and in turn move the prism stage and the prism component to direct radiation toward a target on a substrate; and a prism guide configured to couple the prism base to the frame of the metrology apparatus, the prism guide configured to bend when the prism base is actuated, but remain coupled to the frame.
52. The metrology apparatus of any of the previous clauses, wherein the first, second, and third objective positioners are configured to move the objective stage in the X, Y, and Z directions, and wherein the first and second prism positioners are configured to move the prism stage in the X and Y directions, independently, at different times, and/or simultaneously, to precisely position the objective and/or the prism component for metrology.
53. The metrology apparatus of any of the previous clauses, wherein the first (X direction) prism positioner comprises a single flexible support, and the second (Y direction) prism positioner comprises two flexible supports.
54. The metrology apparatus of any of the previous clauses, wherein the two flexible supports of the second prism positioner are located at or near opposite corners of a first side edge of the prism stage, and the single flexible support of the first prism positioner is located at or near a center of a second side edge of the prism stage.
55. The metrology apparatus of any of the previous clauses, wherein the two flexible supports of the second prism positioner comprise parallel rectangular plates, and the single flexible support of the first prism positioner comprises an elongated body having a square or rectangular cross section.
56. A method performed with a metrology apparatus having a prism component and an objective, the method comprising: supporting the objective with an objective stage; coupling first, second, and third objective positioners to the objective stage and moving the objective stage in X, Y, and Z directions respectively, an objective positioner comprising: at least one flexible objective support coupled to the stage, the at least one flexible objective support configured to be relatively stiff in an axial direction of the objective positioner, and relatively flexible in other directions; an objective base coupled to the at least one flexible objective support, the objective base configured to be actuated to move in the axial direction, and in turn move the objective stage and the objective to direct the radiation toward a target on a substrate; and an objective guide configured to couple the objective base to a frame of the metrology apparatus, the objective guide configured to bend when the objective base is actuated, but remain coupled to the frame; supporting the prism component with a prism stage; and coupling first and second prism positioners to the prism stage and moving the prism stage in X and Y directions respectively, a prism positioner comprising: at least one flexible prism support coupled to the prism stage, the at least one flexible prism support configured to be relatively stiff in an axial direction of the prism positioner, and relatively flexible in other directions; a prism base coupled to the at least one flexible prism support, the prism base configured to be actuated to move in the axial direction, and in turn move the prism stage and the prism component to direct radiation toward a target on a substrate; and a prism guide configured to couple the prism base to the frame of the metrology apparatus, the prism guide configured to bend when the prism base is actuated, but remain coupled to the frame.
57. The method of any of the previous clauses, wherein the first, second, and third objective positioners are configured to move the objective stage in the X, Y, and Z directions, and wherein the first and second prism positioners are configured to move the prism stage in the X and Y directions, independently, at different times, and/or simultaneously, to precisely position the objective and/or the prism component for metrology.
58. The method of any of the previous clauses, wherein the first (X direction) prism positioner comprises a single flexible support, and the second (Y direction) prism positioner comprises two flexible supports.
59. The method of any of the previous clauses, wherein the two flexible supports of the second prism positioner are located at or near opposite corners of a first side edge of the prism stage, and the single flexible support of the first prism positioner is located at or near a center of a second side edge of the prism stage.
60. The method of any of the previous clauses, wherein the two flexible supports of the second prism positioner comprise parallel rectangular plates, and the single flexible support of the first prism positioner comprises an elongated body having a square or rectangular cross section.

The concepts disclosed herein may be associated with any generic imaging system for imaging sub wavelength features, and may be especially useful with emerging imaging technologies capable of producing increasingly shorter wavelengths. Emerging technologies already in use include EUV (extreme ultra violet), DUV lithography that is capable of producing a 193 nm wavelength with the use of an ArF laser, and even a 157 nm wavelength with the use of a Fluorine laser. Moreover, EUV lithography is capable of producing wavelengths within a range of 20-5 nm by using a synchrotron or by hitting a material (either solid or a plasma) with high energy electrons in order to produce photons within this range.

While the concepts disclosed herein may be used for imaging on a substrate such as a silicon wafer, it shall be understood that the disclosed concepts may be used with any type of lithographic imaging systems, e.g., those used for imaging on substrates other than silicon wafers. In addition, the combination and sub-combinations of disclosed elements may comprise separate embodiments. For example, one or more of the elements and/or operations described above may be included in separate embodiments, or they may be included together in the same embodiment.

The descriptions above are intended to be illustrative, not limiting. Thus, it will be apparent to one skilled in the art that modifications may be made as described without departing from the scope of the claims set out below.

1. A positioning system for an optical element of a metrology apparatus, the positioning system comprising:
a stage; and
a positioner comprising:
at least one flexible support coupled to the stage, the at least one flexible support configured to be relatively stiff in an axial direction of the positioner, and relatively flexible in other directions;
a base coupled to the at least one flexible support, the base configured to be actuated to move in the axial direction, and in turn move the stage; and
a guide configured to couple the base to a frame of the metrology apparatus, the guide configured to bend when the base is actuated.

2. The system of claim 1, wherein the positioning system comprises first, second, and third positioners coupled to the stage and configured to move the stage in X, Y, and Z directions respectively.

3. The system of claim 2, wherein the first, second, and third positioners are configured to move the stage in the X, Y, and Z directions independently, at different times and/or simultaneously, to precisely position the optical element for metrology, the optical element supported by the stage.

4. The system of claim 2, wherein the first positioner comprises a single flexible support, the second positioner comprises two flexible supports, and the third positioner comprises at least three flexible supports.

5. The system of any of claim 2, wherein the third positioner comprises four flexible supports positioned at or near four corresponding corners of the stage.

6. The system of claim 4, wherein the single flexible support of the first positioner is located at or near a center of a first side edge of the stage.

7. The system of claim 6, wherein the two flexible supports of the second positioner are located at or near opposite corners of a second side edge of the stage, the two flexible supports configured to reduce or prevent undesired rotation of the stage.

8. The system of claim 7, wherein the at least three flexible supports of the third positioner are coupled to a top surface of the stage and configured to reduce or prevent undesired rotation and/or tilt of the stage.

9. The system of claim 8, wherein the at least three flexible supports of the third positioner are positioned around a porro prism of the metrology apparatus.

10. The system of claim 1, wherein the optical element is an objective.

11. The system of claim 1, wherein the guide comprises two parallel flexible plates positioned on opposite sides of the base.

12. The system of claim 1, wherein the frame is a sensor frame of the metrology apparatus.

13. The system of claim 1, wherein the positioner is configured to move the optical element for overlay measurements.

14. The system of claim 13, wherein the overlay measurements are for a semiconductor wafer, and are made as part of a semiconductor manufacturing process.

15. The system of claim 1, wherein the positioner further comprises an actuator coupled to the base configured to move the base in the axial direction, and in turn move the stage and an optical element supported by the stage.

16. A metrology apparatus comprising:
a radiation output configured to provide radiation directed toward an objective along an optical path;
a positioning system comprising:
a stage configured to support the objective; and
first, second, and third positioners coupled to the stage and configured to move the stage in X, Y, and Z directions respectively, a positioner comprising:
at least one flexible support coupled to the stage, the at least one flexible support configured to be relatively stiff in an axial direction of the positioner, and relatively flexible in other directions;
a base coupled to the at least one flexible support, the base configured to be actuated to move in the axial direction, and in turn move the stage and the objective to direct the radiation toward a target on a substrate; and
a guide configured to couple the base to a frame of the metrology apparatus, the guide configured to bend when the base is actuated, but remain coupled to the frame; and
a detector, the detector configured to receive diffracted and reflected radiation from the target and generate a detection signal.

17. The metrology apparatus of claim 16, further comprising a second positioning system, the second positioning system configured to position a second objective to facilitate two simultaneous measurements on the same substrate.

18. The metrology apparatus of claim 16, wherein the first, second, and third positioners are configured to move the stage in the X, Y, and Z directions independently, at different times and/or simultaneously, to precisely position an objective for metrology.

19. The metrology apparatus of claim 16, wherein the first positioner comprises a single flexible support, the second positioner comprises two flexible supports, and the third positioner comprises three flexible supports.

20. A metrology apparatus comprising:
a prism component;
an objective;
an objective positioning system comprising:
an objective stage configured to support the objective; and
first, second, and third objective positioners coupled to the objective stage and configured to move the objective stage in X, Y, and Z directions respectively, an objective positioner comprising:
at least one flexible objective support coupled to the stage, the at least one flexible objective support configured to be relatively stiff in an axial direction of the objective positioner, and relatively flexible in other directions;
an objective base coupled to the at least one flexible objective support, the objective base configured to be actuated to move in the axial direction, and in turn move the objective stage and the objective to direct the radiation toward a target on a substrate; and
an objective guide configured to couple the objective base to a frame of the metrology apparatus, the objective guide configured to bend
when the objective base is actuated, but remain coupled to the frame; and a prism positioning system comprising:
a prism stage configured to support the prism component; and
first and second prism positioners coupled to the prism stage and configured to move the prism stage in X and Y directions respectively, a prism positioner comprising:
at least one flexible prism support coupled to the prism stage, the at least one flexible prism support configured to be relatively stiff in an axial direction of the prism positioner, and relatively flexible in other directions;
a prism base coupled to the at least one flexible prism support, the prism base configured to be actuated to move in the axial direction, and in turn move the prism stage and the prism component to direct radiation toward a target on a substrate; and
a prism guide configured to couple the prism base to the frame of the metrology apparatus, the prism guide configured to bend when the prism base is actuated, but remain coupled to the frame.
